(19) United States
(12) Patent Application Publication
(10) Pub. No.: US 2024/0191343 A1
(43) Pub. Date: Jun. 13, 2024

(54) MASK-FRAME ASSEMBLY AND PRODUCING METHOD THEREOF

(71) Applicant: Olum Material Corporation, Yongin-si (KR)

(72) Inventor: Taek Yong JANG, Seongnam-si (KR)

(73) Assignee: Olum Material Corporation, Yongin-si (KR)

(21) Appl. No.: 18/531,521

(22) Filed: Dec. 6, 2023

(30) Foreign Application Priority Data
Dec. 7, 2022 (KR) 10-2022-0169600
Dec. 12, 2022 (KR) 10-2022-0173037
Dec. 15, 2022 (KR) 10-2022-0176180
Dec. 28, 2022 (KR) 10-2022-0186973

(51) Int. Cl. C23C 16/04

(52) U.S. Cl. CPC C23C 16/042; H10K 71/166

(57) ABSTRACT

The present invention relates to a mask-frame assembly and a producing method thereof. The mask-frame assembly according to the present invention is used in a process of forming organic light-emitting diode (OLED) pixels on a semiconductor wafer, and includes: a support including an edge portion and a grid portion; a mask connected onto the support and including a mask pattern; and an adhering support connected to a lower part of the support and including an auxiliary edge portion and an auxiliary grid portion, wherein the adhering support includes a magnetic material.

### CROSS-REFERENCE TO RELATED APPLICATION(S)

This application claims the benefit under 35 USC § 119(a) of Korean Patent Application No. 10-2022-0169600, filed on Dec. 7, 2022, No. 10-2022-0173037, filed on Dec. 12, 2022, No. 10-2022-0176180, filed on Dec. 15, 2022, No. 10-2022-0186973, filed on Dec. 28, 2022, in the Korean Intellectual Property Office, the entire disclosure of which is herein incorporated by reference for all purposes.

### BACKGROUND

### 1. Field

The following description relates to a mask-frame assembly and a producing method thereof. More specifically, the following description relates to a mask-frame assembly that is used in forming pixels on a semiconductor wafer and enables a mask pattern of ultra-high resolution to be precisely formed, and a producing method thereof.

### 2. Description of Related Art

As a technology to form pixels in the OLED manufacturing process, the FMM (Fine Metal Mask) method is mainly used, which deposits organic materials at a desired location by attaching a thin metal mask (shadow mask) to the substrate.

In a conventional OLED manufacturing process, after a mask thin film is prepared, a mask is welded and fixed to an OLED pixel deposition frame and then is used. In the fixing process, there is a problem in that the mask of a large area is not well aligned. Also, in the process of welding and fixing the mask to the frame, there is a problem in that the mask sags or twists with the load since the mask film is too thin and has a large area.

In an ultra-high-resolution OLED manufacturing process, small defects of less than 1 μm may lead to pixel deposition failure, and thus there is a need to develop technology that is capable of preventing deformation of a mask, such as sagging or twisting of a mask, and clearly aligning the mask.

Recently, a microdisplay which is applied to a virtual reality (VR) device has drawn attention. A microdisplay is required to provide a much smaller screen size than those of the existing displays and still realize high quality within the small screen in order to display an image directly in front of a user's eye in a VR device. Therefore, smaller mask patterns than those of a mask used in the existing ultra-high-resolution OLED manufacturing process and a finer alignment of the mask before a pixel deposition process are required.

### SUMMARY

Therefore, the present invention is devised to solve the above-mentioned problems of the related art and provides a mask-frame assembly capable of realizing ultra-high definition pixels of a microdisplay, and a producing method thereof.

Moreover, the present invention provides a mask-frame assembly capable of enhancing stability of pixel deposition by allowing a mask to be clearly aligned, and a producing method thereof.

In addition, another object of the present invention is to provide a mask-frame assembly providing a uniform stress level over the whole surface of a mask and a producing method thereof.

In addition, another object of the present invention is to provide a mask-frame assembly enabling a mask and frame to adhere to a target substrate without being distorted by a load during an organic light-emitting diode (OLED) pixel formation process, and a producing method thereof.

However, these objects are merely illustrative, and the scope of the present invention is not limited thereto.

The present invention provides a mask-frame assembly for use in a process of forming OLED pixels on a semiconductor wafer, the mask-frame assembly including a support including an edge portion and a grid portion; a mask connected onto the support and including a mask pattern; and an adhering support connected to a lower part of the support and including an auxiliary edge portion and an auxiliary grid portion, wherein the adhering support includes a magnetic material.

A thickness of the adhering support may be thicker than a thickness of the support.

The auxiliary grid portion may have a thinner thickness than the auxiliary edge portion, and a thickness of the auxiliary edge portion of the adhering support is thicker than a thickness of the support.

The adhering support and the support may be connected to each other by means of a weld bead.

A welding groove may be formed towards the support from an exposed surface of the auxiliary edge portion, and the weld bead may be formed within the welding groove.

The weld bead may be formed to protrude from an exposed surface of the auxiliary grid portion.

The edge portion of the support may have a circular shape, the mask may have a circular shape, and the adhering support may have a shape corresponding to the support.

The grid portion may include a plurality of first grid portions extending in a first direction and having both ends connected to the edge portion; and a plurality of second grid portions extending in a second direction perpendicular to the first direction, intersecting with the first grid portions, and having both ends connected to the edge portion.

The support may be formed from a silicon wafer, and the mask may be formed on a conductive substrate by electroforming.

The mask may include a dummy portion connected onto the edge portion; a plurality of cell portions disposed at a central part of the mask and including a plurality of mask patterns; and separation portions positioned closer to the central part of the mask than the dummy portion and disposed between the plurality of cell portions, and the separation portions may include a plurality of dummy cell portions including a plurality of dummy patterns formed to pass through the dummy portion or formed to a predetermined depth on the dummy portion.

Each of the cell portions including the plurality of mask patterns may have a rectangular shape, and each dummy cell portion including the plurality of dummy patterns may have a shape with at least some side exhibiting curvature.

An adhesive portion may be interposed between the support and the adhering support, and the adhesive portion may include at least one of Cu, Au, Ag, Al, Sn, In, Bi, Zn, Sb, Ge, or Cd.

A connection portion may be interposed between the support and the mask, and the connection portion may include at least one of Fe, Ni, or Si.

A surface resistance of the support may be 5×10⁻⁴ ohm·cm to 1×10⁻² ohm·cm.

In addition, the present invention may provide a producing method of a mask-frame assembly for use in a process of forming OLED pixels on a semiconductor wafer, comprising the steps of: (a) preparing a laminate of a support including an edge portion and a grid portion and a mask formed on the support by electroforming and including a mask pattern; (b) preparing an adhering support including an auxiliary edge portion and an auxiliary grid portion; and (c) connecting the adhering support onto a surface opposite to a surface of the support connected to the mask, wherein the adhering support includes a magnetic material.

Step (a) may include: (a1) preparing a conductive substrate; (a2) forming a mask including a mask pattern on a first surface of the conductive substrate; and (a3) forming the support including the edge portion and the grid portion by etching the conductive substrate on a second surface opposite to the first surface of the conductive substrate.

Between steps (a2) and (a3), a protective portion may be formed on the mask.

The producing method may further include, between steps (a2) and (a3), (a2′) forming an adhesive portion including at least one of Cu, Au, Ag, Al, Sn, In, Bi, Zn, Sb, Ge, or Cd on a second surface opposite to a first surface of the conductive substrate, and in step (3), the conductive substrate and the adhesive portion may be etched.

In step (c), heat treatment may be performed on the support, the adhesive portion, and the adhering support to connect the support to the adhering support by means of the adhesive portion.

The producing method may further include, between steps (a2) and (a2′), or after step (c), forming a connection portion including at least one of Fe, Ni, or Si between the mask and the support by performing heat treatment on the mask and the support.

Other features and aspects will be apparent from the following detailed description, the drawings, and the claims.

### BRIEF DESCRIPTION OF THE DRAWINGS

FIG. 1 is a schematic view illustrating a mask-frame assembly according to a first embodiment of the present invention.

FIG. 2 is a schematic cross-sectional view taken along line A-A′ of FIG. 1.

FIG. 3 illustrates a schematic plan view and schematic cross-sectional views taken along, respectively, lines E-E′ and F-F′ showing a mask according to an embodiment of the present invention.

FIG. 4 is a schematic plan view showing a support according to an embodiment of the present invention.

FIG. 5 illustrates a schematic plan view and a schematic cross-sectional view taken along line G-G′ showing a mask according to another embodiment of the present invention.

FIGS. 6 to 10 are schematic views showing the producing process of a mask-frame assembly according to an embodiment of the present invention.

FIGS. 11 to 13 are schematic views specifically showing the process of connecting a support and an adhering support during the producing process of a mask-frame assembly according to an embodiment of the present invention.

FIGS. 14 and 15 are schematic views showing the producing process of a mask-frame assembly according to a second embodiment of the present invention.

FIGS. 16 and 17 are schematic views showing the producing process of a mask-frame assembly according to a third embodiment of the present invention.

FIG. 18 is a schematic diagram of an organic light emitting diode (OLED) pixel deposition apparatus to which a mask-frame assembly according to an embodiment of the present invention is applied.

FIG. 19 is a schematic cross-sectional view of a mask-frame assembly according to a fourth embodiment of the present invention.

FIGS. 20 to 22 are schematic views showing the producing process of a mask-frame assembly according to a fourth embodiment of the present invention.

FIGS. 23 and 24 are schematic views showing the producing process of a mask-frame assembly according to a fifth embodiment of the present invention.

FIGS. 25 and 26 are schematic views showing the producing process of a mask-frame assembly according to a sixth embodiment of the present invention.

FIGS. 27 to 29 are schematic views specifically showing the process of connecting a support and an adhering support during the producing process of a mask-frame assembly according to the sixth embodiment of the present invention.

FIGS. 30 and 31 are schematic views showing the producing process of a mask-frame assembly according to a seventh embodiment of the present invention.

FIG. 32 is a schematic diagram of an OLED pixel deposition apparatus to which a mask-frame assembly according to another embodiment of the present invention is applied.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following detailed descriptions of the invention will be made with reference to the accompanying drawings illustrating specific embodiments of the invention by way of example. These embodiments will be described in detail such that the invention can be carried out by one of ordinary skill in the art. It should be understood that various embodiments of the invention are different, but are not necessarily mutually exclusive. For example, a specific shape, structure, and characteristic of an embodiment described herein may be implemented in another embodiment without departing from the scope of the invention. In addition, it should be understood that a position or placement of each component in each disclosed embodiment may be changed without departing from the scope of the invention. Accordingly, there is no intent to limit the invention to the following detailed descriptions. The scope of the invention is defined by the appended claims and encompasses all equivalents that fall within the scope of the appended claims. In the drawings, like reference numerals denote like functions, and the dimensions such as lengths, areas, and thicknesses of elements may be exaggerated for clarity.

Hereinafter, to allow one of ordinary skill in the art to easily carry out the invention, embodiments of the present invention will be described in detail with reference to the accompanying drawings.

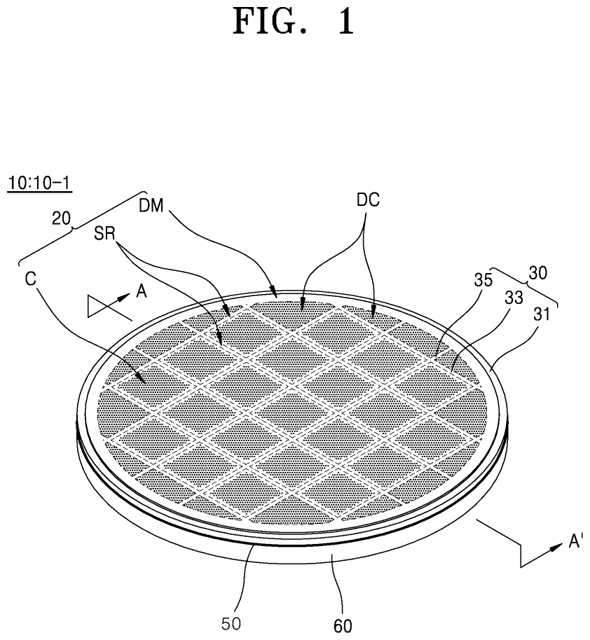

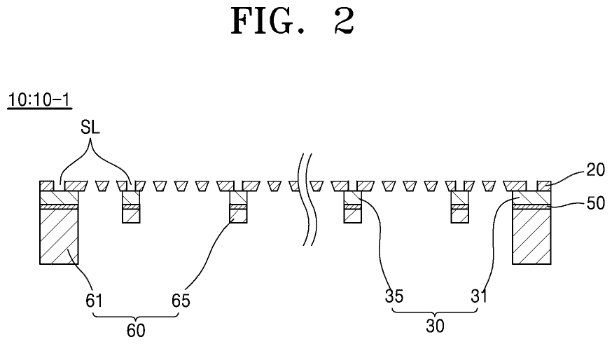

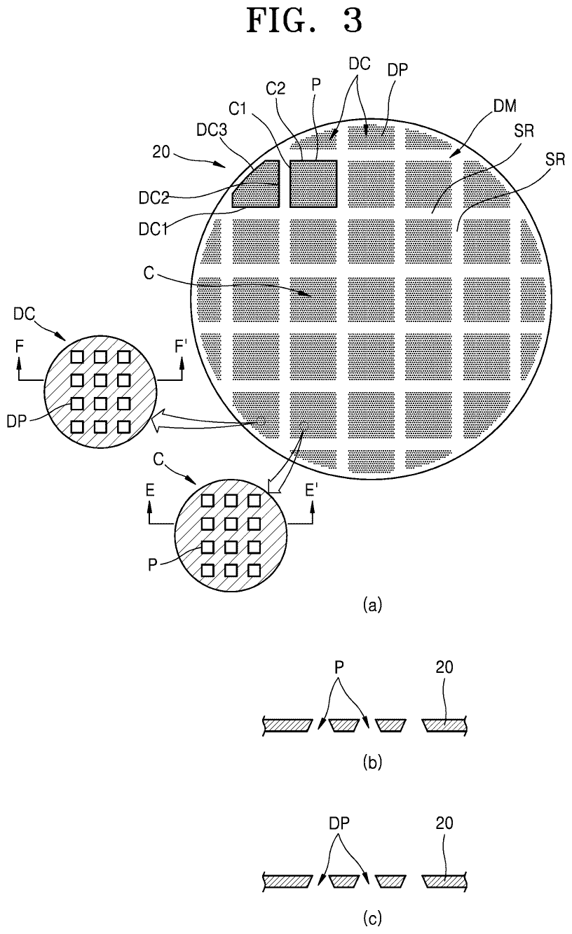

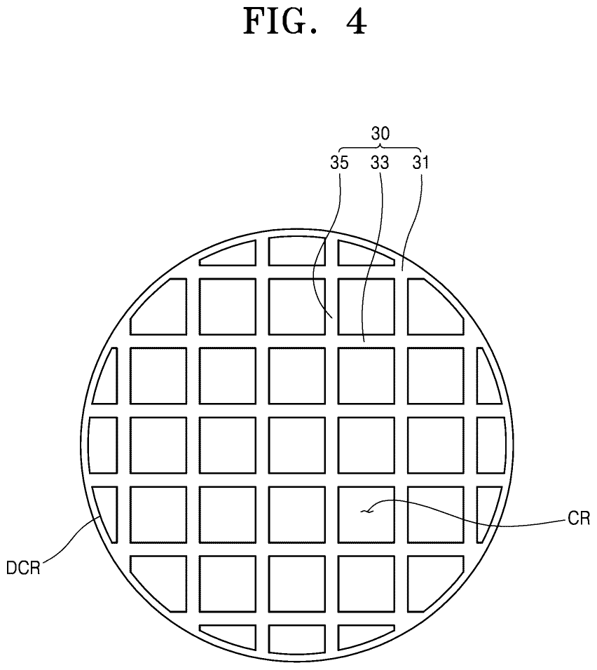

FIG. 1 is a schematic view illustrating a mask-frame assembly 10 (10-1) according to a first embodiment of the present invention. FIG. 2 is a schematic cross-sectional view taken along line A-A′ of FIG. 1. FIG. 3 illustrates a schematic plan view and schematic cross-sectional views taken along, respectively, lines E-E′ and F-F′ showing a mask 20 according to an embodiment of the present invention. FIG. 4 is a schematic plan view showing a support 30 according to an embodiment of the present invention.

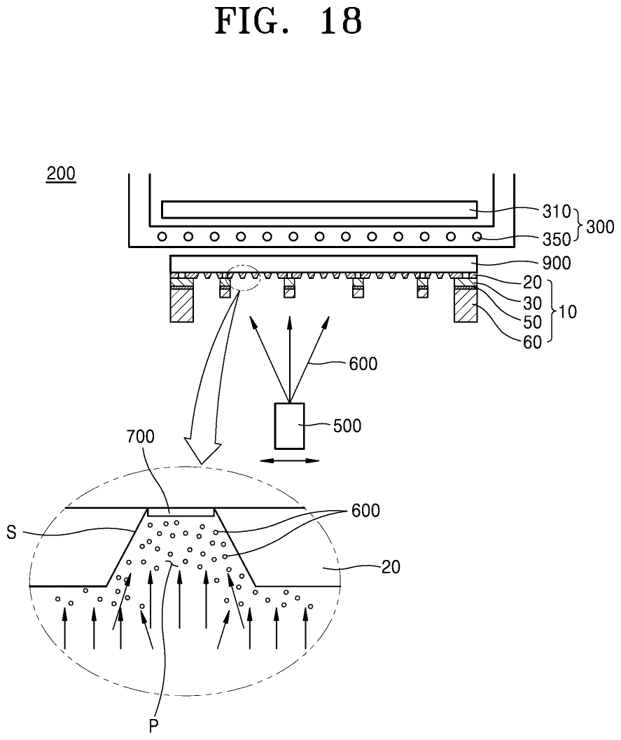

A microdisplay, which is recently applied to a virtual reality (VR) device, may be used in a pixel deposition process for a target substrate 900 (see FIG. 18), such as a silicon wafer or a silicon wafer, rather than for a substrate of a large area. The microdisplay has a screen that is about 1 to 2 inches smaller than the size of the large area substrate because a screen is positioned directly in front of an eye of a user. Moreover, implementation of higher resolution is required since the screen is positioned closely in front of the eye of the user. Moreover, implementation of higher resolution is required since the screen is positioned closely in front of the eye of the user.

Accordingly, the present invention is directed to provide a mask-frame assembly 10 which, rather than being used in a pixel formation process for a target substrate of a large area with a side length exceeding 1,000 mm, allows for a pixel formation process on a semiconductor silicon target wafer 900 of 200 mm, 300 mm, or 450 mm such that ultra-high-resolution pixels are formed, and a producing method thereof.

For example, currently, quad high definition (QHD) image quality is 500 to 600 pixels per inch (PPI), wherein a size of each pixel is about 30 to 50 μm, and a 4K ultra-high definition (UHD) or 8K UHD image quality has a resolution of up to 860 PPI or up to 1,600 PPI, which is higher than the QHD image quality. A microdisplay directly applied to a VR device or a microdisplay inserted into a VR device is aimed at realizing ultra-high resolution of approximately 2,000 PPI or higher and has a pixel size of about 5 to 10 μm. In the case of a semiconductor wafer or a silicon waver, a finer and more precise process is possible compared to a glass substrate by utilizing technologies developed in a semiconductor process, and hence the semiconductor wafer or silicon wafer may be employed as a substrate of a high-resolution microdisplay. The present invention is characterized by a mask-frame assembly 10 that allows for formation of pixels on the silicon wafer.

Referring to FIGS. 1 and 2, the present invention is characterized in that a mask 20 has a shape corresponding to a semiconductor wafer (or a silicon wafer) in order to perform a pixel deposition process on the semiconductor wafer as a target substrate 900 (see FIG. 18). When the shape of the mask 20 corresponds to the semiconductor wafer, it means that the mask 20 has the same shape and size as those of the semiconductor wafer or that the mask 20 has a different size and shape from the semiconductor wafer but is coaxial to the semiconductor wafer while mask patterns P are disposed within the shape of the semiconductor wafer. In addition, the mask 20 that has a shape corresponding to the semiconductor wafer is characterized in that it is integrally connected to the support 30 and is thereby clearly aligned.

The mask-frame assembly 10 may include the mask 20, the support 30, and an adhering support 60. The support 30 may be connected onto one surface of the adhering support 60, and the mask 20 may be connected onto one surface of the support 30. The support 30 and the adhering support 60 may serve as a frame that supports the mask 20.

Referring to FIGS. 1 to 3, the mask 20 may include cell portions C, separation portions SR, and a dummy portion DM. Each cell portion C is a portion of the mask 20 that is not in contact with the support 30 and where the mask patterns P are formed, each separation portion SR is a portion disposed between the cell portions C, and the dummy portion DM is a portion attached to the support 30. Although the cell portion C, the separation portion SR, and the circular dummy portion DM may be denoted by different names and reference characters according to the formed positions thereof, the cell portion C, the separation portion SR, and the dummy portion DM are not separated regions and are configured to be integrally formed with the same material. In other words, the cell portion C, the separation portion SR, and the circular dummy portion DM are each part of the mask 20, which are simultaneously formed in an electroforming process. Hereinafter, the cell portion C, the separation portion SR, and the dummy portion DM may be used interchangeably with the mask 20.

The mask 20 preferably includes an Invar or Super Invar material. Alternatively, the mask 20 may include a metal material that can be electroformed with nickel (Ni), cobalt (Co), titanium (Ti), chromium (Cr), tungsten (W), molybdenum (Mo), or the like and capable of forming silicide with a silicon component of the support 30. Alternatively, the mask 20 may include a Super Invar material containing three or more components, including Co. The mask 20 may have a circular shape to correspond to the circular semiconductor wafer. The mask 20 may have a size corresponding to or greater than a silicon wafer of 200 mm, 300 mm, 450 mm, or the like.

A conventional mask has a shape of rectangle, polygon, or the like to correspond to a substrate of a large area. In addition, a frame also has a shape of rectangle, polygon, or the like to correspond to the mask. Since the mask has angled corners, there may be a problem in that stress is concentrated on the corners. Concentration of stress may cause different force to act on only a portion of the mask, which may twist or distort the mask, leading to a failure of pixel alignment. In particular, at an ultra-high resolution of 2,000 PPI or higher, stress concentration on the corners of the mask should be avoided.

Thus, as the mask 20 of the present invention has a circular shape, the mask 20 does not have any corners. That is, the dummy portion DM of the mask 20 may have a circular shape and have no corners. Since there is no corner, it is possible to solve the problem that different force acts on a specific portion of the mask 20, and the stress may be uniformly distributed along a circular edge. Accordingly, the mask 20 may contribute to clear pixel alignment without being twisted or distorted, and mask patterns P of 2,000 PPI or higher may be realized. The edges of the mask 20 may positioned inward of the edges of the support 30, match the edges of the support 30, or be formed to encase the sides of the edges of the support 30. The present invention performs a pixel deposition process by matching a circular semiconductor wafer (or a circular silicon wafer) having a low coefficient of thermal expansion and the circular mask 20 in which the stress is uniformly distributed along the edge, so that pixels with a size of approximately 5 to 10 μm may be deposited.

A plurality of mask patterns P may be formed in the cell portion C. The mask patterns P may be a plurality of plurality pixel patterns P that correspond to red (R), green (G), and blue (B) pixels. Sides of each mask pattern P may have a sloped shape, a tapered shape, or a shape in which a pattern width gradually increases from the upper part toward the lower part. A number of mask patterns P may be grouped to form a single display cell portion C. The display cell portion C may have a diagonal length of approximately 1 to 2 inches, and may be a portion that corresponds to one microdisplay. Alternatively, the display cell portion C may be a portion that corresponds to a plurality of displays.

The mask pattern P may have a substantially tapered shape, and may have a pattern width of several to several tens of μm, preferably of approximately 5 to 10 μm (resolution of 2000 PPI or higher).

The mask 20 may include a plurality of cell portions C. The plurality of cell portions C may be arranged at predetermined intervals in a first direction (x-axis direction) and in a second direction (y-axis direction) that is perpendicular to the first direction. In FIG. 1, it is shown that 21 cell portions C are arranged along the first and second directions, but the present invention is not limited thereto. The separation portion SR may be disposed between the cell portions C. The cell portion C and the separation portion SR are portions that are positioned closer to the central part of the mask 20 than the dummy portion DM.

Referring to FIGS. 1, 2, and 4, the support 30 may include the edge portion 31, a plurality of first grid portions 33, and a plurality of second portions 35. Although the edge portion 31 and the first and second grid portions 33 and 35 may be denoted by different names and reference characters, the edge portion 31 and the first and second grid portions 33 and 35 are not separated regions and are configured to be integrally formed with the same material. Hereinafter, the edge portion 31 and the first and second grid portions 33 and 35 may be used interchangeably with the support 30.

The support 30 is preferably made of a silicon material, and more preferably, the support 30 may be formed from a silicon wafer and made of a silicon material. The edge portion 31 of the support 30 may have a circular shape such that the support 30 corresponds to a circular semiconductor wafer that is a target substrate 900 (see FIG. 18). The support 30 may have a shape of the same size or at least larger than the mask 20 so that the mask 20 can be connected to an upper part of the support 30.

The edge portion 31 may define the outer shape of the support 30 with an edge shaped corresponding to the mask 20. The edge portion 31 may have a circular shape.

The plurality of first grid portions 33 may extend in the first direction and connect at both ends to the edge portion 31. In addition, the plurality of second grid portions 35 may extend in the second direction perpendicular to the first direction, intersecting with the first grid portions 33, and connect at both ends to the edge portion 31. The first grid portions 33 are arranged in parallel to each other with predetermined intervals, and the second grid portions 35 are also arranged in parallel to each other with predetermined intervals. Also, since the first and second grid portions 33 and 35 intersect with each other, empty regions CR, in the form of a matrix, may appear at the intersecting portions. These empty regions CR where the cell portions C of the mask 20 are disposed are referred to as “cell regions CR” (see FIG. 4).

The thickness of the support 30 may be greater than the thickness of the mask 20. In order to realize mask patterns P of 2,000 PPI or higher, the thickness of the mask 20 may be approximately 2 μm to 12 μm. If the mask 20 is thicker than the aforementioned thickness, it may be difficult to form the mask patterns P, having an overall tapered shape, to have the width or spacing that meets the desired resolution. The support 30 may be formed at a scale of tens of micrometers to millimeters to provide sufficient rigidity to support the mask 20.

On the other hand, in the case where the cell portion C of the mask 20 is in quadrilateral shape, if only the cell portion C is formed on the mask 20, there may be a problem of uneven stress levels in each region of the cell portion C and the dummy portion DM with a circular edge. Furthermore, when only the cell portion C is formed, as there are no separately penetrating openings in the dummy portion DM, the dummy portion DM deforms less under stress, while the cell portion C exhibits significant deformation under the same stress. The mask-frame assembly 10 should maintain a clear position of the cell portion C to construct ultra-high-resolution OLED pixels. Therefore, it is necessary to uniformly align the stress levels acting on the cell portion C and the dummy portion DM. This may be equally applied to the cell region CR and a dummy cell region DCR of the support 30.

Referring back to FIGS. 1 to 3, a plurality of dummy cell portions DC may be formed in the mask 20 of the present invention. The plurality of dummy cell portions DC may be arranged at predetermined intervals in a first direction (x-axis direction) of the cell portion C and in a second direction (y-axis direction) that is perpendicular to the first direction. The predetermined interval between the dummy cell portion DC and the cell portion C may correspond to predetermined interval between the cell portions C. A separation portion SR may also be disposed between the dummy cell portion DC and the cell portion C.

A length of at least one side DC1 or DC2 of the dummy cell portion DC may correspond to a length of one side C1 or C2 of the cell portion C. The cell portion C may be provided in a quadrilateral shape, and edge sides C1 and C2 of the cell portion C may be formed as straight lines perpendicular to each other. The dummy cell portion DC may be arranged on an extended line of the cell portion C along the first and second directions, but it may be difficult to provide the dummy cell portion DC in a quadrilateral shape due to the nature of being arranged at the edge of the mask 20. The dummy cell portion DC may have a shape with at least some side DC3 having curvature. From another perspective, two to four edge sides of the dummy cell portion DC may be provided as straight lines, and some sides may be provided as curves. In FIG. 3, for example, the dummy cell portion located in the top-left corner is provided with two sides DC1 and DC2 as straight lines of the same length as the edge sides of the cell portion C, and the remaining side DC3 is provided with two shorter straight lines and one shorter curve compared to the edge side of the cell portion C. In another example, the rightmost/leftmost dummy cell portions DC and the uppermost/lowermost dummy cell portions DC may have a substantially angular “C” shape with three sides provided as straight lines, and one side thereof is provided as a curved line.

In addition, a plurality of dummy patterns DP may be formed in the dummy cell portion DC. As shown in FIGS. 2 and 3, the dummy patterns DP may be formed to have the same shape as the mask patterns P. For example, sides of each dummy pattern P may have a sloped shape, a tapered shape, or a shape in which a pattern width gradually increases from the upper part toward the lower part. The plurality of dummy patterns DP may be grouped to form a single dummy cell portion DC. The dummy pattern DP may have a substantially tapered shape, and may have a pattern width of several to several tens of μm, preferably of approximately 5 to 10 μm (resolution of 2,000 PPI or higher).

Meanwhile, the dummy patterns DP may be formed to a predetermined depth even if they penetrate the mask 20 in a thickness direction as long as they maintain uniformity of stress in the entire area of the mask 20. Also, the dummy patterns DP may not necessarily have the same shape and size as the mask patterns P, but may be greater than the mask patterns P and may have a shape other than a tapered shape as long as they maintain uniformity of stress in the entire area of the mask 20. However, as the shapes of dummy patterns P and the mask patterns P are more identical to each other, the uniformity of stress levels may increase.

Referring to FIG. 4, a plurality of dummy cell regions DCR may be formed in the support 30. The plurality of dummy cell regions DCR may be arranged at predetermined intervals in a first direction (x-axis direction) of the cell region CR and in a second direction (y-axis direction) that is perpendicular to the first direction. The predetermined interval between the dummy cell region DCR and the cell region CR may correspond to the predetermined interval between the cell regions CR. The first and second grid portions 33 and 35 may also be disposed between the dummy cell regions DCR and the cell regions CR. Since the dummy cell regions DCR serve the same function as the dummy cell portions DC described above, the description thereof will be replaced with the above description of the dummy cell portions DC.

Referring to FIGS. 1 and 2, the adhering support 60 may include an auxiliary edge portion 61, a plurality of first auxiliary grid portions 63, and a plurality of second auxiliary grid portions 65. Although the auxiliary edge portion 61 and the first and second auxiliary grid portions 63 and 65 may be denoted by different names and reference characters, the auxiliary edge portion 61 and the first and second auxiliary grid portions 63 and 65 are not separated regions and are configured to be integrally formed with the same material. Hereinafter, the auxiliary edge portion 61 and the first and second auxiliary grid portions 63 and 65 may be used interchangeably with the adhering support 60.

The adhering support 60 preferably includes a magnetic material. In contrast, the support 30, which is a silicon wafer, may not include a magnetic material. For example, the adhering support 60 may include either Fe or Ni. Additionally, as an example, the adhering support 60 may be made of Invar material. With the inclusion of a magnetic material in the adhering support 60, in FIG. 18 to be described below, a magnetic field generated by a magnet 310 pulls the adhering support 60 towards a target substrate 900, and consequently, the mask 20 and the support 30 on the top of the adhering support 60 can adhere to the target substrate 900. As a result, distortion or sagging of the mask 20 and the support (30) due to loads or tension may be prevented.

The adhering support 60 may have a shape corresponding to the support 30. The adhering support 60 may have the same shape as the support 30 shown in FIG. 3. However, it is not necessary for the adhering support 60 to have the same shape as the support 30, as long as it is a shape that can be connected to a lower part of the support 30 and transmit adhesion force to the mask 20 and the support 30 on the top when the magnetic field is applied by the magnet 310 (see FIG. 18). In this case, the cell portion C of the mask 20 and the cell region CR of the support 30 should remain uncovered and open by the adhering support 60.

The auxiliary edge portion 61 may have a circular shape corresponding to the edge portion 31 of the support 30.

The plurality of first auxiliary grid portions 63 may extend in the first direction and connect at both ends to the auxiliary edge portion 61. In addition, the plurality of second auxiliary grid portions 65 may extend in the second direction perpendicular to the first direction, intersecting with the first auxiliary grid portions 63, and may connect at both ends to the auxiliary edge portion 61. The first auxiliary grid portions 63 are arranged in parallel to each other with predetermined intervals, and the second auxiliary grid portions 65 are also arranged in parallel to each other with predetermined intervals.

Since the first and second auxiliary grid portions 63 and 65 intersect with each other, cell regions CR, in the form of a matrix, may appear at the intersecting portions. Additionally, dummy cell areas DCR may appear between the auxiliary edge portion 61 and the first and second auxiliary grid portions 63 and 65.

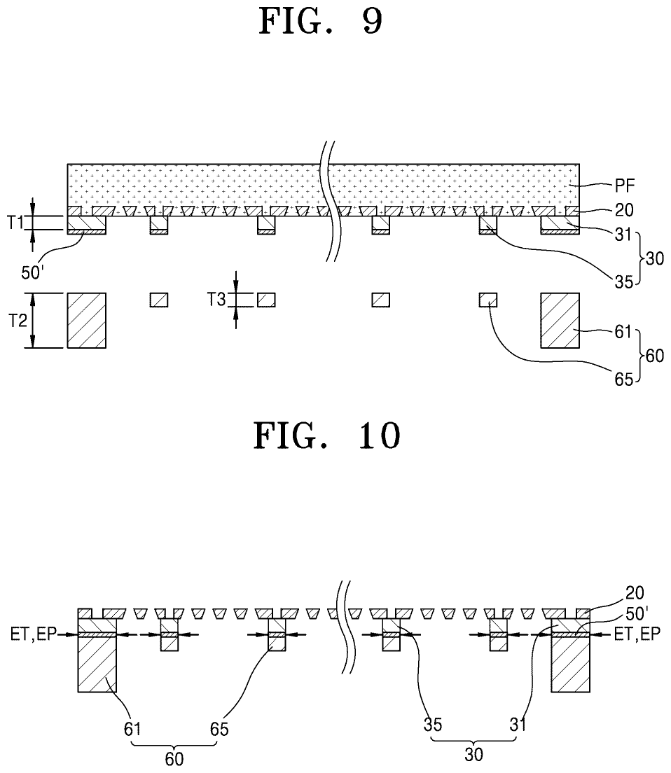

The adhering support 60 needs to effectively transmit adhesion force upward when the magnetic field is applied by the magnet 310, and also to provide sufficient support to prevent deformation of the mask 20 and the support 30. Therefore, it is preferable for the adhering support 60 to have a thickness T2 (see to FIG. 9) thicker than the thickness T1 of the support 30 so as to generate a strong magnetic force and possess strong rigidity. For example, the thickness T1 of the support 30 may be approximately 50 μm to 1,000 μm, and the thickness T2 of the adhering support 60 may be thicker than the thickness T1 of the support 30. The thickness T1 of the support 30 may be approximately 800 μm to 1,000 μm when directly applying a silicon wafer, and approximately 50 μm to 300 μm when thinning one side of the silicon wafer. If the thickness T2 of the adhering support 60 is too thin, it may have weak rigidity and may not generate enough magnetic force. On the other hand, if the thickness T2 of the adhering support 60 is thicker than 5 mm, it may incur high manufacturing costs and pose difficulties in processing. The preferable thickness T2 of the adhering support 60 is approximately 0.1 mm to 5 mm, more preferably approximately 2 mm to 3 mm.

In the adhering support 60, the thickness T3 of the auxiliary grid portions 63 and 65 may be thinner than the thickness T2 of the auxiliary edge portion 61. The aforementioned thickness T2 of the adhering support 60 may correspond to the thickness T2 of the auxiliary edge portion 61. Since it needs to accommodate the cell regions CR through which organic substances 600 can pass between the auxiliary grid portions 63 and 65, it is preferable for the thickness T3 to be thin. For example, the thickness T3 of the auxiliary grid portions 63 and 65 may correspond to the thickness of the support 30 and may be preferably approximately 50 μm to 200 μm. However, the thickness is not necessarily limited to this, and the thickness T3 of the auxiliary grid portions 63 and 65 may be the same as the thickness T2 of the auxiliary edge portion 61.

Meanwhile, an adhesive portion 50 may be interposed between the support 30 and the adhering support (60). By means of the adhesive portion 50, the support 30 and the adhering support 60 may be connected to each other. The adhesive portion 50 may include at least one metal. For example, the adhesive portion 50 may be made of at least one of Cu, Au, Ag, Al, Sn, In, Bi, Zn, Sb, Ge, or Cd. Specific details of the adhesive portion 50 will be described further below.

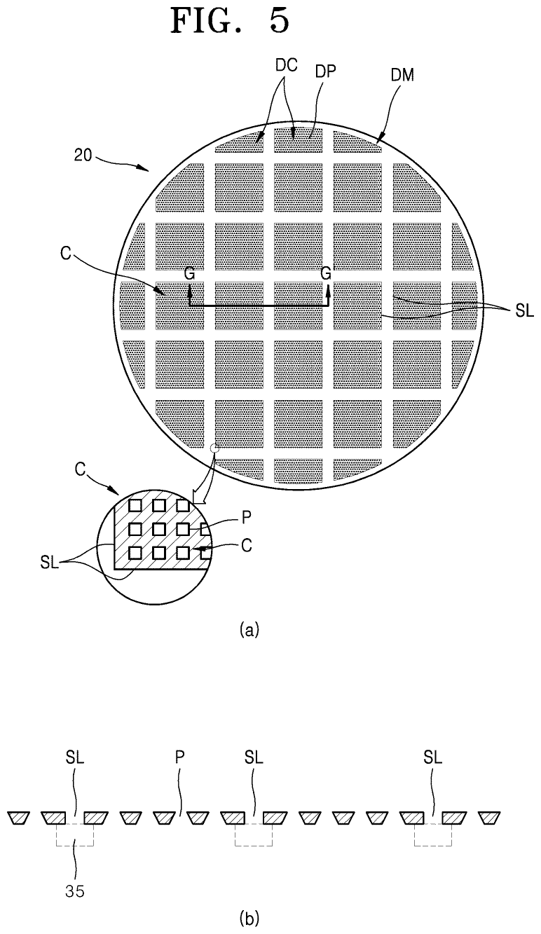

FIG. 5 illustrates a schematic plan view and a schematic cross-sectional view taken along line G-G′ showing a mask according to another embodiment of the present invention.

A mask 20 according to another embodiment may include a plurality of cell portions C that include a plurality of mask patterns P. Each cell portion C may have slit lines SL formed between them. The cell portions C may be spaced apart from each other by the slit lines SL. Additionally, each pair of neighboring cell portions C may be supported at one side on the same grid portion 35. Referring to (b) of FIG. 5, it can be seen that the right and left sides of two neighboring cell portions C are supported on a second grid portion 35 represented by a dotted line.

Unlike the mask 20 in which the cell portions C are connected to each other through the separation portions SR as shown in FIG. 2, the cell portions C of the mask 20 of FIG. 5 may be spaced apart from each other by the slit lines SL. The surface of the underlying support 30 (an edge portion 31 and the first and second grid portions 33 and 35) may be exposed between the cell portions C by the slit lines SL. As will be described below, the slit lines SL provide a path for a laser L to pass, and through the exposed support 30, the laser L may be emitted to weld the support 30 and the adhering support 60. In addition, since each cell portion C is not connected by the slit lines SL and exists independently, residual stress during the subsequent heat treatment H process may only be present in each cell portion C.

In the following, the description will be made assuming that the cell portions C of the mask 20 are spaced apart from each other by the slit lines SL.

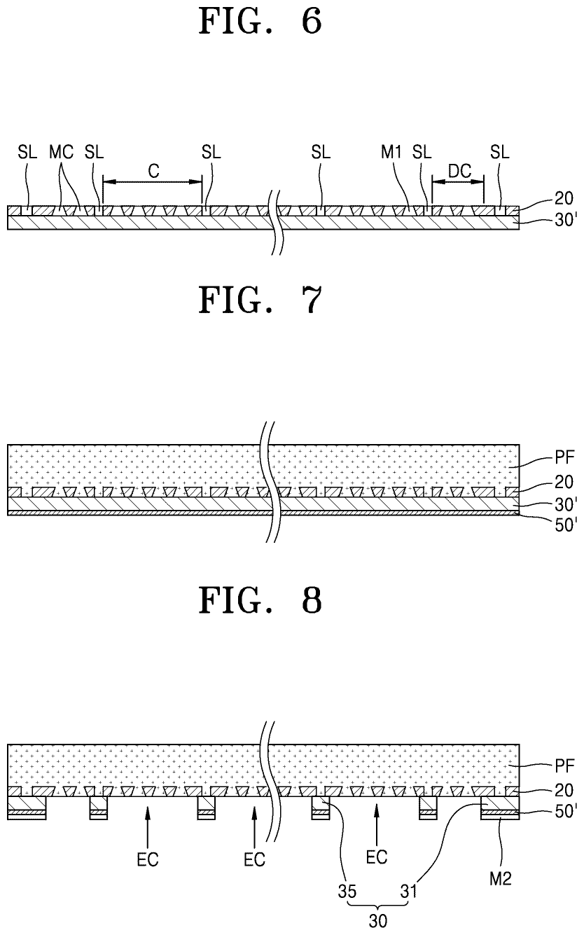

FIGS. 6 to 10 are schematic views showing the producing process of the mask-frame assembly 10 (10-1) according to an embodiment of the present invention.

Referring to FIG. 6, a support 30′, which is a conductive substrate 30′, is prepared. The support 30′ may be made of a conductive material to enable electroforming. To achieve both conductivity and low resistance, the support 30′ may be highly doped at a concentration higher than or equal to 10¹⁹ cm⁻³. The doping may be performed over the entire support 30′ or on only the surface of the support 30′. According to one embodiment, the surface resistance of the support 30′ may be 5×10⁻⁴ to 1×10⁻² ohm·cm. The support 30′ may be used as a cathode electrode during electroforming.

Unlike metals with a metal oxide on the surface and polycrystalline silicon with grain boundaries, doped monocrystalline silicon, being free of defects, allows for the uniform formation of an electric field across the entire surface during electroforming, which results in a uniform plated film (or mask 20). The mask 20 prepared with the uniform plated film may further improve the image quality of OLED pixels. Additionally, as there is no need for additional processes to remove or address defects, costs for process is reduced and the productivity is improved.

The support 30′, which is a conductive substrate 30′ made of silicon wafer, may be provided by reducing the thickness of at least one surface of the silicon wafer. For example, the support 30′ with a thickness of approximately 800 μm may be reduced to a thickness of approximately 50 μm to 200 μm. Alternatively, the support 30′ may be used without reducing its thickness.

Then, a patterned insulating portion M1 may be formed on one surface of the support 30′. The insulating portion M1 is a part formed to protrude (embossed) from one surface of the support 30′, and may have insulation properties to prevent the formation of the plated film (or the mask 20). Accordingly, the insulating portion M1 may be made of at least one of a photoresist material, a silicon oxide material, or a silicon nitride material. The insulating portion M1 may be formed by forming a silicon oxide or a silicon nitride on the support 30′ using deposition or the like, and thermal oxidation or thermal nitridation may be used using the support 30′ as a base. A photoresist may be formed using a printing method or the like. The insulating portion M1 may be preferably thicker than the plated film to be formed.

The insulating portion M1 may preferably have a tapered shape. When forming patterns in a tapered shape using a photoresist, a multiple exposure method, a method of varying an exposure intensity per region, or the like may be utilized.

In addition to the insulating portion M1, a patterned insulating portion MC (or a dummy insulating portion MC) may be further formed on one surface of the support 30′. The insulating portion M1 may be formed on a region corresponding to the cell portion C and the insulating portion MC may be formed on a region corresponding to the dummy cell portion DC. The shape of the insulating portion MC may be the same as that of the insulating portion M1. The insulating portion MC and the insulating portion M1 may be formed together in the same process.

Then, the mask 20 may be formed by performing electroforming on the support 30′. The support 30′ is used as a cathode body and an anode body (not shown) facing the support 30′ is prepared. The anode body may be immersed in a plating solution (not shown), and the support 30′ may be partially or entirely immersed in the plating solution. Since the insulating portion M1 has the insulating properties, a plated film is not formed on a portion that corresponds to the insulating portion M1, allowing for the construction of a mask pattern P of the mask 20. The mask pattern P (or the insulating portion M1) may be formed on a region that corresponds to the cell portion C. Additionally, due to the insulating layer M1, slit lines SL between the cell portions C may also be formed during the electroforming process.

Since the insulating portion MC has the insulating properties, a plated film is not formed on a portion that corresponds to the insulating portion MC, allowing the construction of a dummy pattern DP of the mask 20. The dummy pattern DP (or the insulating portion MC) may be formed on a region that corresponds to the dummy cell portion DC.

Meanwhile, the composition of the mask 20 may be controlled so that the mask 20 has a coefficient of thermal expansion (CTE) similar to that of a silicon material of the support 30′. The mask 20 should have a similar CTE to the support 30′ to prevent warping of the mask 20 on the support 30′, which serves as a frame. In addition, this may minimize changes in pixel position accuracy (PPA), which is the alignment error of cell portions C and mask patterns P on the support 30′.

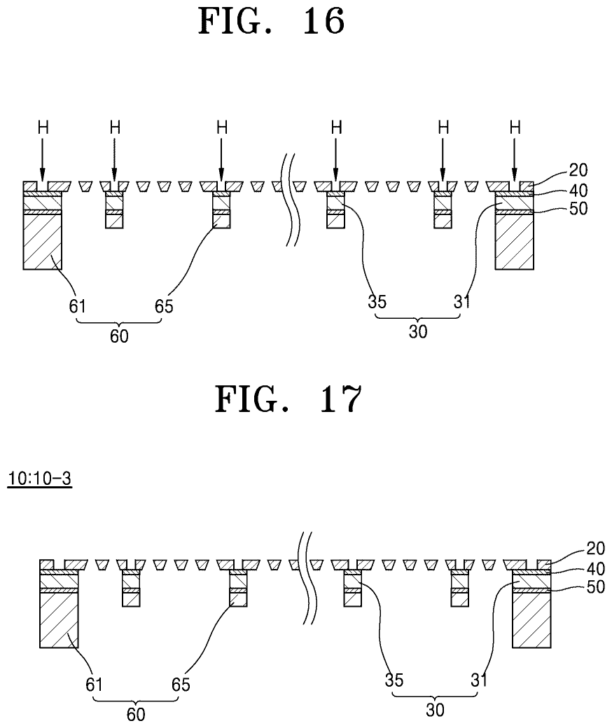

Taking this into account, the composition of the mask 20 may be controlled so that the CTE of the support 30′ made of silicon and the CTE of the mask 20 after the heat treatment H which will be described in FIG. 16 become approximately (3.5±1)×10⁻⁶/° C. Even if the mask 20 is made of Invar, electroforming with varying the composition ratio of Fe and Ni may be performed to control the CTE of the mask 20 to be most similar to that of the support 30′ made of silicon. Alternatively, depending on the process temperature conditions, the CTE of the mask 20 may be controlled to be smaller or larger than that of the support 30′ to allow the mask 20 to tightly connect onto the support 30′.

Additionally, the mask 20 may be configured as a laminate with two or more plated layers such that the mask 20 has a CTE similar to that of a silicon material of the support 30′. In this case, a first mask layer may be formed of a metal material capable of forming silicide with the support 30′. The first mask layer may be formed of a material, such as Ni, Co, Ti, Cr, W, Mo, or the like, which exhibits high adhesion to the support 30′ when produced by electroforming. A second mask layer may be made of a material, such as Invar, Super Invar, or the like, which exhibits a low CTE, when produced by electroforming. As the first and second mask layers have different CTEs, the CTE of the mask 20 may be controlled by adjusting the thickness ratio of the first and second mask layers. The thickness ratio of the first and second mask layers may be controlled by adjusting the electroforming duration.

On the other hand, electroforming may be performed to allow the mask 20 to be formed on both the upper and side surfaces of the support 30′, rather than being formed only on the upper surface. In the case of performing heat treatment H which will be described below, if the mask 30 is formed only on the upper surface of the support 30′, there is a risk that the edge portion of the mask 20 will be peeled off during the heat treatment H process, and thus a plated film may also be formed further on the side surface of the support 30′. Accordingly, as the plated film on the side surface reinforces the adhesion to the support 30′ on the side surface of the support 30′, the entire mask 20 may not be peeled off during the heat treatment H process, and may be well fixed and adhered to the support 30′. The plated film on the side surface may be removed later by etching or laser cutting.

Also, in the case of performing heat treatment H which will be described below, the mask 20 formed by electroforming needs to be well adhered to the support 30′ without peeling off. To this end, other approaches may be considered in addition to electroforming on the upper and side surfaces of the support 30′.

As one of methods, a native oxide of the support 30′ on which electroforming is performed may be controlled. An oxide may be formed on the surface of the support 30′ made of a silicon wafer material. This oxide layer on the surface may disrupt the uniform electric field, resulting in uneven formation of the plated film (mask 20) and lower adhesion between the formed plated film (mask 20) and the support 30′. Therefore, a process of removing native oxide is preferably followed by an electroforming process.

As another method, another film may be further formed to mediate adhesion between the plated film (the mask 20) and the support 30′. In addition to a barrier film, which will be described below, a film or a combination of films providing adhesion to both surfaces of the film may be used.

Alternatively, the surface of the support 30′ may be pre-treated before electroforming. Through physical treatment or chemical treatment, the plated film (the mask 20) produced in the electroforming process may be formed to have stronger adhesion on the support 30′. In addition, by controlling the plating method in the electroforming process, the plated film (the mask 20) may be formed to have stronger adhesion on the support 30′.

Next, referring to FIG. 7, an adhesive portion 50′ may be formed on a lower surface (second surface) of the support 30′, which is opposite to an upper surface (first surface) in contact with the mask 20. The adhesive portion 50′ may include at least one of Cu, Au, Ag, Al, Sn, In, Bi, Zn, Sb, Ge, or Cd. The adhesive portion 50′ may be formed by sputtering, brazing, or other methods that enable easy deposition of a film without material limitations, but is not limited thereto.

On the other hand, after removing the insulating portions M1 and MC, a protective portion PF may be further formed on the mask 20. The protective portion PF may be provided as a surface protection film. The protective portion PF may protect the surface of the mask 20 during the formation process of the adhesive portion 50′ and the subsequent etching EC process of the support 30′ and the adhesive portion 50′, which will be described below. Additionally, the protective portion PF may fix and support the mask 20 and the support 30′ in an attached state during the etching EC process of the support 30′, preventing deformation of the support 30′.

Then, referring to FIG. 8, the support 30′ may be subjected to etching EC. Etching EC may be performed on the second surface (lower surface) opposite to the first surface (upper surface) of the support 30′ to which the mask 20 is adhered. Etching EC may be performed on a region of the support 30′ corresponding to the cell portions C of the mask 20. A region that corresponds to the separation portion SR of the mask 30 is not subjected to etching. Additionally, etching EC may be performed on regions of the support 30′ corresponding to the dummy cell portions DC of the mask 20. Etching EC may also be performed on the adhesive portion 50′, and etching EC of the adhesive portion 50′ and the support 30′ may be performed in a single process or separate processes.

The support 30 after etching EC may take a form including the edge portion 31 and the grid portions 33 and 35. The lower surface of the edge portion 31 and the grid portions 33 and 35 may have the adhesive portion 50′ formed on their lower surfaces. To ensure clear visibility of the edge portion 31 and the grid portions 33 and 35, it is preferable to use a dry etching method with anisotropic etching characteristics. Since the support 30′ is a silicon wafer, there is an advantage in that etching EC may be performed by utilizing existing semiconductor-related technologies and micro-electro mechanical system-related technologies.

In order to impart etch resistance, an insulating portion M2 may be formed on the lower surface of the support 30′ excluding the portions corresponding to the cell portions C and the dummy cell portions DC. The insulating portion M2 may be formed of photoresist using a printing method or the like, and may be formed of silicon oxide or silicon nitride serving as a hard mask by a method such as thermal oxidation or thermal nitridation. Meanwhile, a metal may be used as a mask for etching. The exposed portions of the lower surface of the support 30′ and the adhesive portion 50′ not covered by the insulating portion M2 may be subjected to etching EC.

Moreover, the etching EC process in FIG. 8 may employ wet etching, instead of dry etching. Wet etching, having isotropic etching characteristics, may induce undercutting of the insulating layer M2 on the second surface (lower surface) of the support 30′. Also, due to the isotropic etching characteristics, side surfaces of the edge portion 31 and the first and second grid portions 33 and 35 may be formed to be tapered. In this case, since organic material sources 600 can move at an inclined angle along the tapered side surface, shadow effect may be primarily prevented in the support 30 and then secondarily prevented in the tapered mask patterns P.

According to one embodiment, a laminate of the mask 20/the support 30′/the adhesive portion 50′ may be immersed in an etchant for Si wet etching to perform the etching EC. Si etchant may be a solution of ultrapure water with 1 to 25% KOH or NaOH. Alternatively, a solution of ultrapure water with 1 to 25% of TMAH may be used. The etching process may be conducted at temperatures ranging from room temperature to 80° C.

The regions opened by a hard mask such as PR or SiN, SiO, etc., allow silicon (Si) etching to occur, forming the endpoint of etching at the interface between the mask 20 and the support 30′. In other words, only the silicon wafer undergoes etching EC, and the mask 20 may remain unetched.

Furthermore, when Si etching is performed by selecting the orientation of the silicon wafer, anisotropic etching is possible, allowing for the adjustment of the taper inclination angles of the side surfaces of the aforementioned edge portion 31 and the first and second grid portions 33 and 35.

In addition, according to one embodiment, when using an etchant solution with an OH base for Si wet etching, it may be difficult to use conventional PR materials for the insulating portion M2. Therefore, when using an OH-based etchant solution, the insulating portion M2 may be formed using epoxy-based PR or a nitride or oxide-based (such as SiN, SiO, or the like) hard mask.

Moreover, the etching rate of wet etching may vary significantly depending on the crystal orientation of the silicon support 30′. For example, the (100) and (110) planes have a high etching rate for wet etching, whereas the (111) plane has a low etching rate. Accordingly, in the present invention, wet etching and dry etching may be alternately performed to etch (EC) the exposed portions on the lower surface of the support 30′.

Wet etching is characterized by low cost and high productivity, but it exhibits a low etching rate on a specific plane. Dry etching, on the other hand, offers the advantage of uniform etching rates on all planes but comes with higher costs and lower productivity. If etching is solely carried out through dry etching, there is a risk of exceeding the operational limits of etching equipment. Thus, wet etching may be initially performed when the (100) and (110) planes are exposed on the lower surface of the support 30′. When the (111) plane is exposed during the wet etching, the (111) plane may be selectively removed through dry etching, followed by another wet etching.

In addition, without reducing the thickness of the support 30′ in the step of FIG. 6, the thickness of the support 30′ may be reduced before or after the etching EC of the support 30′ in FIG. 8.

Thereafter, referring to FIG. 9, the insulating portion M2 may be removed. Then, the adhering support 60 may be provided. The thickness T2 of the adhering support 60 (or the thickness T2 of the auxiliary edge portion 61) may be greater than the thickness T1 of the support 30. The thickness T3 of the auxiliary grid portions 63 and 65 may be thinner than the thickness T2 of the auxiliary edge portion 61. The adhering support 60 may be provided to allow the formation of the auxiliary edge portion 61 and the first and second auxiliary grid portions 63 and 65 through etching, processing, etc.

Next, referring to FIG. 10, the upper part of the adhering support 60 may be brought into corresponding contact with the lower part of the support 30. The adhering support 60 may contact the support 30 by means of the adhesive portion 50. A process to remove the protective portion PF may be further performed.

Subsequently, at least one of heat ET or pressure EP may be applied to the support 30, the adhesive portion 50′, and the adhering support 60. Heat treatment may be carried out by applying heat ET to the support 30, the adhesive portion 50′, and the adhering support 60. Alternatively, heat treatment may be conducted by simultaneously applying heat ET and pressure EP to the support 30, the adhesive portion 50′, and the adhering support 60 to achieve heat treatment with less heat ET.

Heat treatment by the application of heat ET and pressure EP may be carried out within the range where the adhesive portion 50′ can connect the support 30 and the adhering support 60. For example, the metals in the adhesive portion 50′ may be melted by heat treatment and then solidified again, connecting the support 30 and the adhering support 60. In another example, the connection may be achieved by altering the interfacial state between the support 30 and the adhering support 60 in a manner that metal components of the adhesive portion 50′ diffuse into the support 30 and the adhering support 60, or conversely, the components of the support 30 and the adhering support 60 diffuse into the adhesive portion 50′ or in a manner that the components of the support 30, the adhering support 60, and the adhesive portion 50′ diffuse mutually into each other.

Heat treatment may be performed at temperatures ranging from about 200° C. to 800° C., preferably in the low temperature range of approximately 200° C. to 400° C. Heat treatment may be conducted with the protective portion PF removed.

Following heat treatment, subsequent processes such as cleaning may be performed to complete the producing of the mask-frame assembly 10 as shown in FIG. 2. The form in which the support 30 and the adhering support 60 are connected by means of the adhesive portion 50, the support 30 includes the edge portion 31 and the first and second grid portions 33 and 35, and the mask 20 is connected onto the support 30 may be provided. The cell portion C of the mask 20 may be provided as an area with an open lower part without support from the support 30/adhering support 60, allowing the movement path of the organic material source 600 in the OLED pixel deposition process.

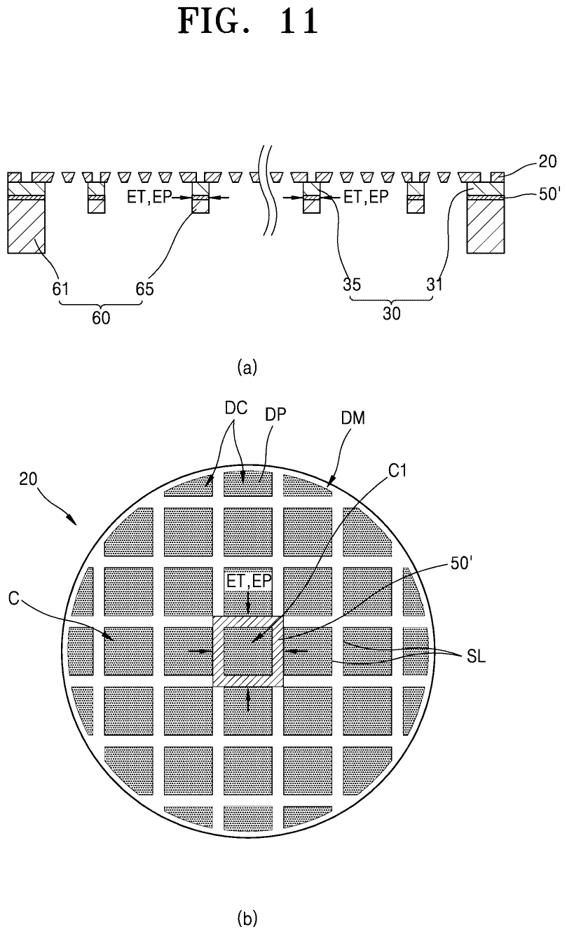

FIGS. 11 to 13 specifically illustrate the process of connecting the support and the adhering support in the producing process of the mask-frame assembly according to one embodiment of the present invention, showing a (a) schematic cross-sectional view and (b) schematic plan view.

As described in FIG. 10, heat ET and pressure EP may be applied to the surrounding areas of all cell portions C to connect the support 30 and the adhering support 60 by means of the adhesive portion 50′. Alternatively, as shown in FIGS. 11 to 13, the support 30 and the adhering support 60 may be sequentially connected on the surrounding area of each cell portion C.

First, referring to FIG. 11, heat ET and pressure EP may be applied only to the surrounding area of the cell portion C1 located at the center of the mask 20 among the cell portions C. The adhesive portion 50′ on the surrounding area of the cell portion C1 may mediate the connection between the support 30 (grid portions 33 and 35) and the adhering support 60 (auxiliary grid portions 63 and 65). The portion of the adhesive portion 50′ connecting the support 30 and the adhering support 60 in the surrounding area of the cell portion C1 is indicated by a shaded rectangle.

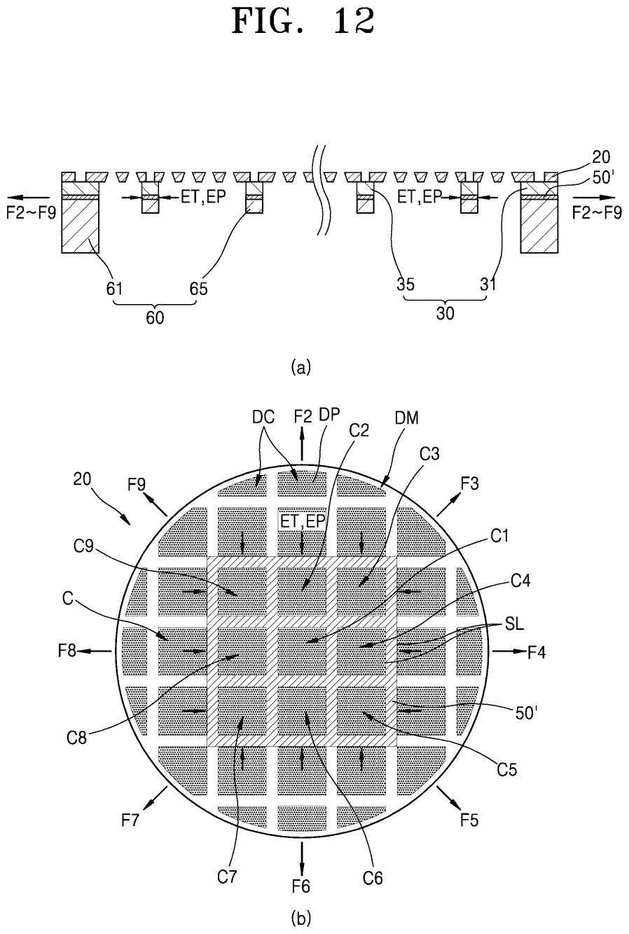

Next, referring to FIG. 12, heat ET and pressure EP may be applied only to the surrounding areas of eight cell portions C2 to C9 neighboring the cell portion C1. The adhesive portion 50′ on the surrounding areas of the cell portions C2 to C9 may mediate the connection between the support 30 (grid portions 33 and 35) and the adhering support 60 (auxiliary grid portions 63 and 65).

Since the surrounding area of cell portion C1 already has the adhesive portion 50 formed, fixing the connection between the support 30 and the adhering support 60, tensile forces F2 to F9 may be applied in a radial direction to the edges of the mask 20 and the support 30. By adjusting the tensile forces F2 to F9, the position alignment of each cell portion C2 to C9 may be further controlled. Heat ET and pressure EP may be applied simultaneously to the surrounding areas of all eight cell portions C2 to C9. Due to the relatively thin thickness T1 of the support 30, ranging from approximately 50 μm to 200 μm, the application of tensile forces F2 to F9 allows for position alignment of the cell portions C2 to C9.

Alternatively, tensile forces F2 to F9 may be applied sequentially from the cell portion C2 to the cell portion C9 in a radial direction or in a 360-degree direction and heat ET and pressure EP may be sequentially applied to the surrounding areas of the cell portions C2 to C9, allowing the adhesive portion 50 to connect the support 30 and the adhering support 60. As an example, in a state where tensile force F2 is applied in the upward direction to the mask and the support 30, heat ET and pressure EP may be applied to the surrounding area of the cell portion C2, so that the support 30 and the adhering support 60 can be connected to the periphery of the cell portion C2 by means of the adhesive portion 50. Subsequently, in a state where tensile force F3 is applied in the upper right direction to the mask 20 and the support 30, heat ET and pressure EP may be applied to the surrounding area of the cell portion C3, so that the support 30 and the adhering support 60 can be connected to the periphery of the cell portion C3 by means of the adhesive portion 50. Subsequently, tensile force F4 may be applied in the right direction to the mask 20 and the support 30, followed by applying heat ET and pressure EP to the surrounding area of the cell portion C4, so that the support 60 and the adhering support 50 can be connected to the periphery of the cell portion C4 by means of the adhesive portion 30. In a state where the surrounding areas of the cell portions C2 to C9 are sequentially aligned by repeating the above process, the support 30 and the adhering support 60 may be connected.

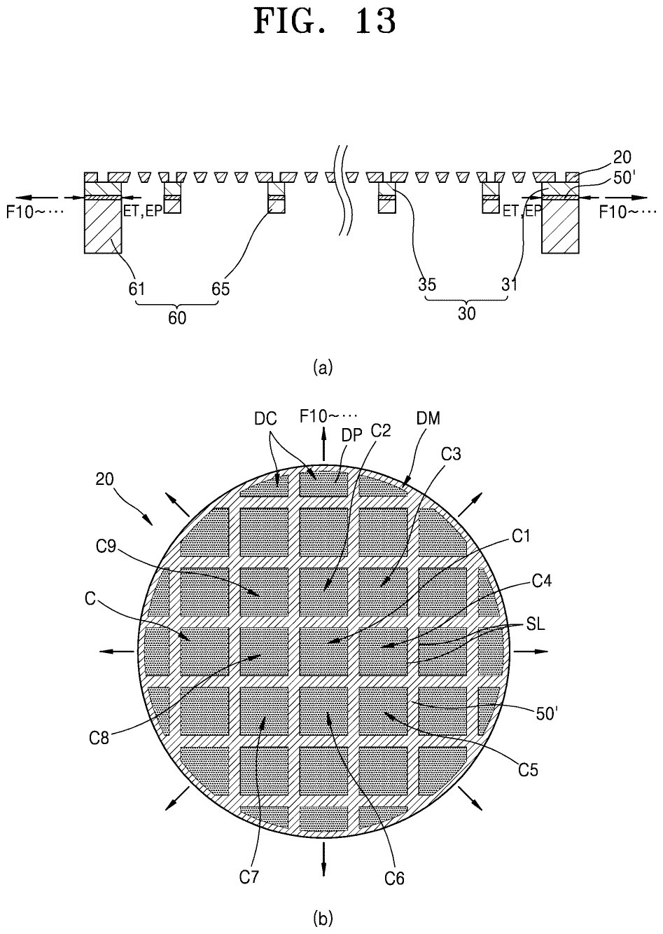

Next, referring to FIG. 13, heat ET and pressure EP may also be applied to the surrounding areas of cell portions C neighboring the eight cell portions C2 to C9 of FIG. 12. The support 30 and the adhering support 60 in the surrounding areas of the cell portions C neighboring the eight cell portions C2 to C9 may be connected simultaneously or sequentially in a radial direction. In the dummy portion DM of the mask 20, the support 30 and the adhering support 60 may also be connected by means of the adhesive portion 50. During the process of adhering the cell portions C neighboring the eight cell portions C2 to C9, tensile forces F10, and so on may be applied to the edges of the mask 20 and the support 30 in a radial direction. This process may be repeated to connect the support 30 and the adhering support 60 on the surrounding areas of all cell portions C.

As described above, the present invention achieves the initial connection of the support 30 and the adhering support 60 around the central cell portion C1, and sequentially aligns the positions of the outer cell portions C and establishes connections of the support 30 and the adhering support 60 around the corresponding cell portion C. This process ensures a clear distinction of the positions of each cell portion C and the mask pattern P of the corresponding cell portion C. Accordingly, the variation in pixel position accuracy (PPA) between each cell portion C may be minimized.

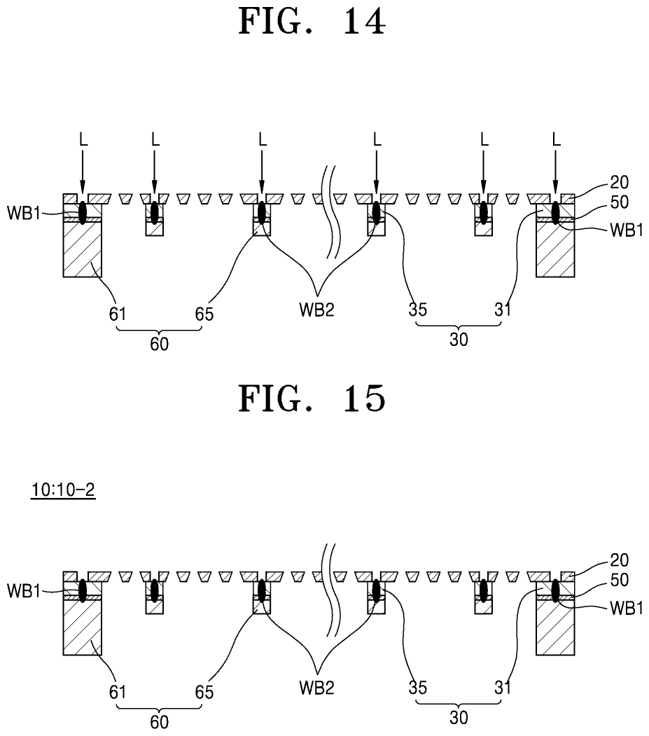

FIGS. 14 to 15 are schematic views showing the producing process of a mask-frame assembly 10 (10-2) according to a second embodiment of the present invention.

Referring to FIG. 14, after performing the processes up to FIG. 10, where the support 30 and the adhering support 60 are connected by means of the adhesive portion 50, laser welding may be further conducted. The laser L may be emitted towards the upper slot lines SL. The laser L may be emitted toward the support 30 (upward direction) exposed through the slot lines SL, resulting in the formation of weld beads WB1 and WB2 at the interface between the support 30 and the adhering support 60.

Referring to FIG. 15, the weld beads WB1 and WB2 may be formed protruding in the upper direction of the support 30. However, since slot lines SL are formed between the cell portions C and the neighboring cell portions C, providing empty spaces, even if the weld beads WB1 and WB2 protrude to a certain height, they do not exceed the height of the upper surface of the mask 20. Accordingly, the protrusion of weld beads WB1 and WB2 on the support 30 or the mask 20 does not affect the position changes of the mask pattern P/cell portion C.

Then, subsequent processes such as cleaning may be performed to complete the producing of the mask-frame assembly 10 (10-2). As the mask-frame assembly involves not only the connections by means of the adhesive portion 50 but also the connections by means of the weld beads WB1 and WB2, the support 30 and the adhering support 60 can be more strongly connected.

FIGS. 16 and 17 are schematic views showing the producing process of a mask-frame assembly 10 (10-3) according to a third embodiment of the present invention.

Referring to FIG. 16, after performing the processes described up to FIG. 10, heat treatment H may be further performed. Heat treatment H may be further performed after completing the processes described up to FIG. 15. Alternatively, heat treatment H may be performed on the support 30′, which is a conductive substrate 30′, after the mask 20 is electroformed (see FIG. 6). Heat treatment H may be performed on both the mask 20 and the support 30′. The heat treatment may be performed in the temperature range of approximately 200° C. to 800° C. In the following description, the example focuses on performing heat treatment H on the mask 20 on the support 30 including the edge portion 31 and the first and second grid portions 33 and 35. However, the same may be applied when heat treatment H is performed after electroforming of the mask 20 on the support 30′, which is a conductive substrate 30′.

Generally, compared to an Invar thin plate produced by rolling, the Invar thin plate produced by electroforming has a higher CTE. Therefore, performing heat treatment on the Invar thin plate may reduce the CTE. However, there might be slight deformation in the Invar thin plate during this heat treatment process. If heat treatment is performed only on the separately existing mask 20, some deformation may occur in the mask pattern P. Therefore, by performing heat treatment while the support 30 and the mask 20 are in an adhered state, it is possible to prevent subtle deformations caused by the heat treatment.

In addition, the Invar thin plate produced by electroforming, and the silicon wafer have almost the same CTE, approximately 3 to 4 ppi Thus, even when the heat treatment H is performed, the mask 20 and the support 30 have the same or similar degree of thermal expansion, preventing misalignment due to thermal expansion and avoiding subtle deformations in the mask pattern P.

Moreover, the present invention is characterized by the connection of the mask 20 and the support 30 through the heat treatment H. During the heat treatment H process, a connection portion 40 may be formed between the mask 20 and the support 30. The connection portion 40 may be provided as an intermetallic compound resulting from the combination of the components of the mask 20 and the support 30. The connection portion 40 may include Ni and Si, Fe, Ni, and Si, or Fe, Ni, and other components in the form of silicide due to the combination of the components of the mask 20, such as Fe and Ni, and the components of the support 30, such as Si. The bonding strength of the intermetallic compound allows the mask 20 and the support 30 to be attached to each other through the connection portion 40.

According to one embodiment, formation conditions of the connection portion 40 provided as a silicide require the following electroforming pre-treatment/electroforming conditions. First, the mask 20 may be electroformed on the support 30 that has been highly doped at a concentration higher than or equal to 10¹⁹ cm⁻³ and has a surface resistance of approximately 5×10⁻⁴ to 1×10⁻² ohm·cm. Second, before electroforming of the mask 20, the surface of the support 30 made of a silicon wafer material may be subjected to HF treatment to form a Si surface with controlled SiO. Third, by initially forming Ni-rich Fe—Ni and adjusting the composition to a Ni content of 35-45%, Ni-silicide may be promoted. Alternatively, before the electroforming of the mask 20 with Fe—Ni composition, a first mask layer of Ni, Co, Ti, etc., may be added as a glue layer to promote the formation of silicide.

Additionally, according to one embodiment, the heat treatment H may be performed at temperatures ranging from 200° C. to 800° C., and the heat treatment H process may be carried out in multiple steps. As a 2-step heat treatment, Ni2Si may be formed in the low temperature range (approximately 250 to 350° C.), adhering the mask 20 to the support 30, followed by gradually raising the temperature to the high-temperature range (approximately 450 to 650° C.) to perform the heat treatment. In the case of an Invar mask produced by electroforming, since it has a microcrystal and/or amorphous structure, when the temperature is rapidly raised during the heat treatment, the Invar mask may be detached or separated from the silicon wafer support due to volume shrinkage. Therefore, it is preferable to perform heat treatment by gradually raising the temperature to high temperature after adhering the Invar mask to the silicon wafer support 30 at low temperature.

In addition, according to one embodiment, a reducing atmosphere should be maintained during the heat treatment H. The reducing atmosphere may be formed as H2, Ar, or N2 atmosphere, and may preferably use a dry N2 gas to prevent oxidation of the Invar mask. In order to prevent oxidation of the Invar mask, the O2 concentration needs to be managed to be less than 100 ppm. Alternatively, a vacuum atmosphere of <10⁻² torr may be formed. The duration may range from 30 minutes to 2 hours.

With the formation of the connection portion 40 (adhesive layer) such as Ni silicide, (Ni, Fe)Si silicide, etc., on the Ni, Fe—Ni interface of the electroformed mask 20 on the silicon wafer support 30, the mask 20 and the support 30 may be connected to each other with the adhesive layer 40 interposed therebetween.

Meanwhile, to control the reaction of Ni and Fe—Ni with Si during the heat treatment H, a barrier film (not shown) may be formed on the support 30′ before electroforming the mask 20 on the support 30′. The barrier film may prevent the components (e.g., Ni and Fe—Ni) of the plated film of the mask 20 from permeating uncontrollably into the silicon support 30′. At the same time, the barrier film preferably has conductivity to allow electroforming to take place on the surface. Taking this into account, the barrier film may include a material, such as titanium nitride (TiN), titanium/titanium nitride (Ti/TiN), tungsten carbide (WC), titanium tungsten (WTi), graphene, or the like. A thin film formation process such as deposition of barrier film may be used without limitations. The barrier film may control the reaction of Fe and Ni with Si so that uniform silicide can be formed and the mask 20 and the connection portion 40 can be attached to each other with appropriate adherence strength. In addition, the barrier film may be configured as a film or a combination of films capable of providing predetermined adhesion or adherence so that the mask 20 is not separated from the support 30′ in a state in which the mask 20 is electroformed on the support 30′.

The thickness of the connection portion 40 (silicide thickness) may be controlled to 10 to 300 nm by adjusting temperature and time, facilitating the connection between the support 30′ and the mask 20.

Meanwhile, the cell portions C of the mask 20 may be spaced apart from each other by the slit lines SL. Consequently, independent residual stresses exist in each cell portion C during the heat treatment H of the mask (20). If the plurality of cell portions C are interconnected, residual stresses due to heat treatment H may occur across the entire portion of the mask 20, increasing the likelihood of deformation, where the edges of the cell portions C may peel away from the support 30 or bend during the heat treatment H process. Therefore, forming the slit lines SL between the cell portions C to separate them may reduce the residual stresses caused by heat treatment H.

Next, referring to FIG. 17, the mask-frame assembly 10 (10-3) according to the third embodiment may have the mask 20 connected onto the support 30 by interposing the connection portion 40 therebetween.

On the other hand, according to one embodiment, the formation of weld beads WB1 and WB2 in FIGS. 14 to 15 and the heat treatment H in FIGS. 16 to 17 may be applied together. In this case, the formation process of weld beads WB1 and WB2 and the heat treatment H process may be performed simultaneously, sequentially, or in reverse order.

As described above, the present invention involves forming a frame by processing and connecting the support 30 and the adhering support 60 without applying a separate physical tension to the mask 20 after forming the mask 20 on the support 30 through electroforming, and thus there is no risk of misalignment of the mask. Accordingly, the mask is clearly aligned so that stability of pixel deposition can be improved and at the same time an ultra-high resolution of 2,000 PPI or higher can be realized.

FIG. 18 is a schematic diagram of an organic light emitting diode (OLED) pixel deposition apparatus 200 to which a mask-frame assembly 10 according to an embodiment of the present invention is applied.

Referring to FIG. 18, the OLED pixel deposition apparatus 200 includes a magnet plate 300 accommodating a magnet 310 and having cooling water lines 350 formed therein, and a deposition source supply 500 configured to supply an organic source 600 from below the magnet plate 300.

A target substrate 900, on which the organic material source 600 is to be deposited, e.g., a glass substrate, may be provided between the magnet plate 300 and the deposition source supply 500. The mask-frame assembly 10 (mask-frame assembly 10 (10-1 to 10-3) according to one of the first to third embodiments) for enabling deposition of the organic material source 600 per pixel may be positioned in contact with or very close to the target substrate 900. The magnet 310 may generate a magnetic field and the mask-frame assembly 10 may adhere to the target substrate 900 due to the attraction by the magnetic field. In this case, the adhering support 60 containing magnetic material is pulled downward toward the target substrate 900. This allows the mask 20 and the support 30 to adhere to the target substrate 900 as the adhering support 60 is pushed upward. Furthermore, during the process in which the adhering support 60 pushes up the mask 20 and the support 30 onto the target substrate 900, issues of unevenness, such as sagging due to self-weight or distortion caused by tension, may also be addressed.

The deposition source supply 500 may supply the organic material source 600 while horizontally reciprocating, and the organic material source 600 supplied from the deposition source supply 500 may pass through mask patterns P formed on the mask-frame assembly 10 and be deposited on a surface of the target substrate 900. The deposited organic material source 600 passing through the mask pattern P of the mask-frame assembly 10 may act as pixels 700 in the OLED.

Since the mask pattern P is formed with sloping sides (tapered shape), the uneven deposition of OLED pixels 700 caused by the shadow effect may be prevented by the organic material source 600 passing through the mask patterns P along the sloped direction.

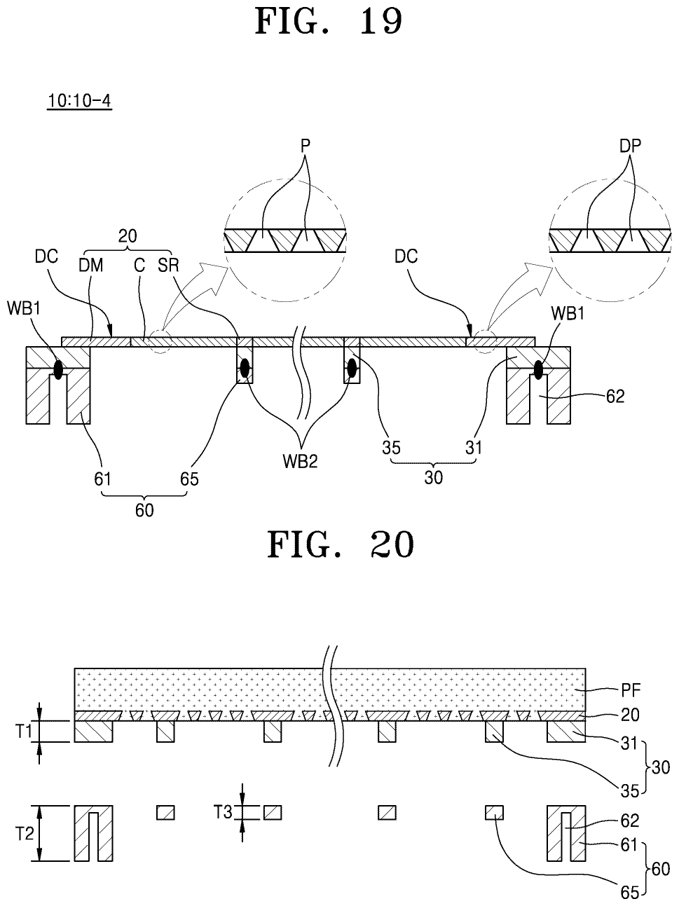

FIG. 19 is a schematic cross-sectional view of a mask-frame assembly 10 (10-4) according to a fourth embodiment of the present invention. FIGS. 20 to 22 are schematic views showing the producing process of the mask-frame assembly 10 (10-4) according to the fourth embodiment of the present invention. In the following description, for the same configurations, the description will be replaced with the description of the structure and producing process described above with reference to FIGS. 1 to 10, and only different configurations will be described.

The processes described in FIGS. 5 to 8 may be similarly applied to the producing process of the mask-frame assembly 10 (10-4). However, the process of forming the adhesive portion 50′ on the lower surface (second surface), which is the opposite surface to the upper surface (first surface) in contact with the mask 20, of the support 30′ in FIGS. 7 and 8 may be excluded.

Following the processes in FIGS. 5 to 8, referring to FIG. 20, the insulating portion M2 may be removed. Then, the adhering support 60 may be provided. The adhering support 60 may be provided to allow the formation of the auxiliary edge portion 61 and the first and second auxiliary grid portions 63 and 65 through etching, processing, etc.

On the other hand, a welding groove 62 may be formed on the lower part of the auxiliary edge portion 61 in an upward direction. The welding groove 62 may be formed concurrently during the process of forming the auxiliary edge portion 61 and the first and second auxiliary grid portions 63 and 65 on the adhering support 60, or it may be formed through a separate process such as etching or machining. The welding groove 62 may be formed in plural at intervals along the circular direction, which is the formation direction of the auxiliary edge portion 61.

Additionally, although not illustrated, optionally, welding grooves may be formed on the first and second auxiliary grid portions 63 and 65 using laser welding within the necessary range to sufficiently form weld beads WB2.

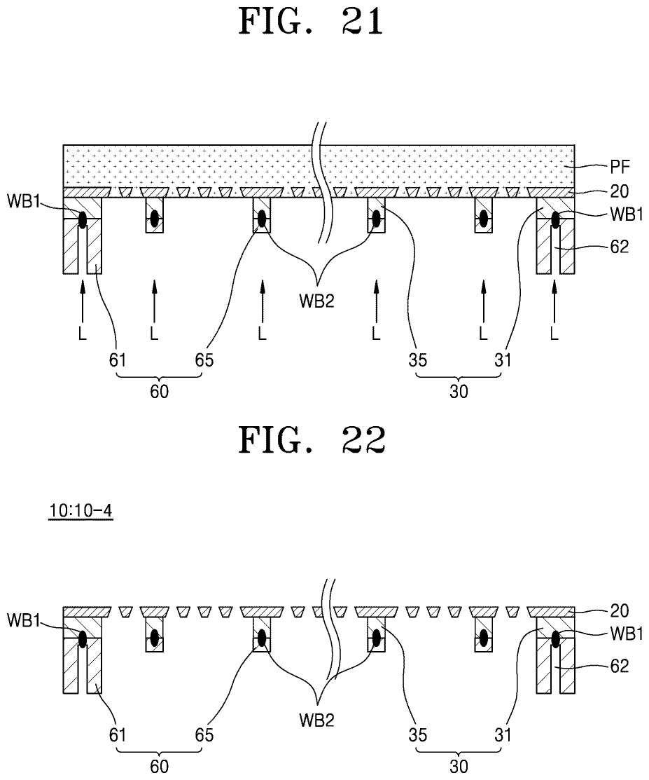

Next, referring to FIG. 21, the upper part of the adhering support 60 may be brought into corresponding contact with the lower part of the support 30. Then, a laser L may be emitted from the lower part of the adhering support 60. The laser L may be emitted from the exposed lower surface of the adhering support 60 in an upward direction (or toward the support 30). The weld beads WB1 and WB2 may be formed at the interface between the adhering support 60 and the support 30, allowing the adhering support 60 and the support 30 to be mutually attached and connected.

Since the thickness T3 of the first and second auxiliary grid portions 63 and 65 are thinner than that of the auxiliary edge portion 61, the weld beads WB2 may be formed even with a laser L of low output power at the interface of the first and second grid portions 33 and 35 of the support 30.

Furthermore, since the welding groove 62 is formed on the auxiliary edge portion 61, the section of the auxiliary edge portion 61 where the welding bead WB1 is practically formed may be made thinner. Consequently, even with a laser L of low output power, the weld bead WB1 may be formed inside the welding groove 62, allowing the attachment of the support 30 and the adhering support 60.

The laser L is emitted from the exposed lower surface of the adhering support 60. Therefore, the weld beads WB1 and WB2 may be formed to protrude in the downward direction (or, towards the exposed surface of the adhering support 60) rather than being formed to protrude in the upward direction. Accordingly, the protrusion of weld beads WB1 and WB2 on the support 30 or the mask 20 does not affect the position changes of the mask pattern P/cell portion C.

The protective portion PF may protect the surface of the mask 20 during the welding connection process between the support 30 and the adhering support 60, and simultaneously, it may fix and support the mask 20 and the support 30 in an attached state, preventing deformation during the welding process.

Next, referring to FIG. 22, after removing the protective portion PF and performing subsequent processes such as cleaning, the producing of the mask-frame assembly 10 (10-4) may be completed. The form in which the support 30 and the adhering support 60 are connected, the support 30 includes the edge portion 31 and the first and second grid portions 33 and 35, and the mask 20 is connected onto the support 30 may be provided. The cell portion C of the mask 20 may be provided as an area with an open lower part without support from the support 30/adhering support 60, allowing the movement path of the organic material source 600 in the OLED pixel deposition process.

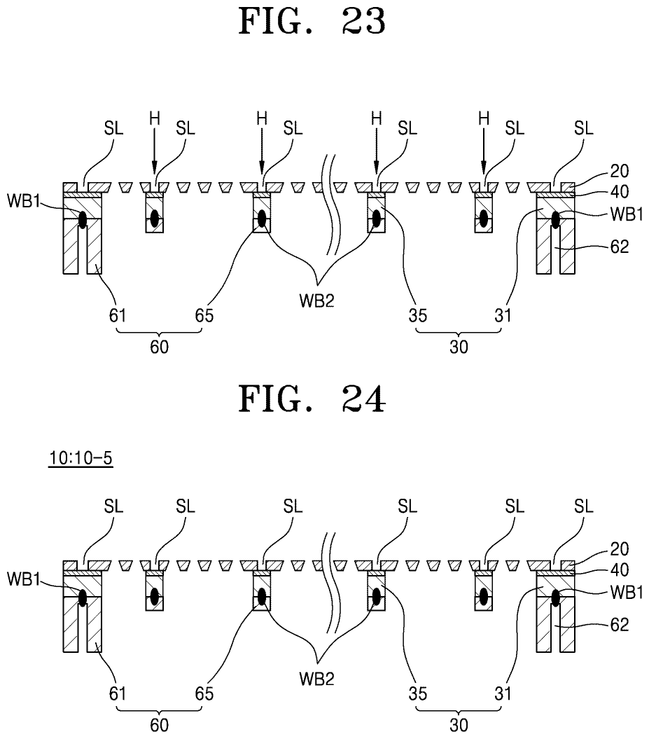

FIGS. 23 and 24 are schematic views showing the producing process of a mask-frame assembly according to a fifth embodiment of the present invention.

Referring to FIG. 23, after performing the processes described up to FIG. 22, heat treatment H may be further performed. Alternatively, heat treatment H may be performed on the support 30′, which is a conductive substrate 30′, after the mask 20 is electroformed (see FIG. 6). Heat treatment H may be performed on both the mask 20 and the support 30. The heat treatment may be performed in the temperature range of approximately 200° C. to 800° C. In the following description, the example focuses on performing heat treatment H on the mask 20 on the support 30 including the edge portion 31 and the first and second grid portions 33 and 35. However, the same may be applied when heat treatment H is performed after electroforming of the mask 20 on the support 30′, which is a conductive substrate 30′.

As a result of the heat treatment H, the mask 20 and the support 30 may can be connected. During the heat treatment H process, a connection portion 40 may be formed between the mask 20 and the support 30. The heat treatment H may be applied in the same manner as described in FIG. 10 and FIG. 16.

Next, referring to FIG. 24, the mask-frame assembly 10 (10-5) according to the fifth embodiment may have the mask 20 connected onto the support 30 by interposing the connection portion 40 therebetween.

On the other hand, according to one embodiment, the formation of weld beads WB1 and WB2 in FIGS. 14 to 15 and the heat treatment H in FIGS. 23 and 24 may be applied together. In this case, the formation process of weld beads WB1 and WB2 and the heat treatment H process may be performed simultaneously, sequentially, or in reverse order.

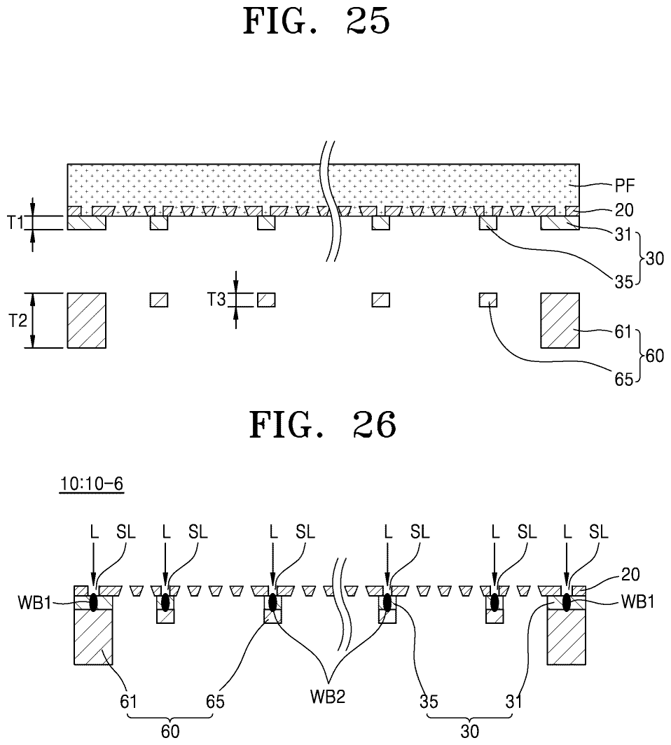

FIGS. 25 and 26 are schematic cross-sectional views showing a connection body 10: 10-6 of a mask and a frame according to a sixth embodiment of the present invention.

The mask-frame assembly 10 (10-6) in FIG. 25 may be provided by applying a mask 20 with slit lines SL formed between each cell portion C as shown in FIG. 5 in the step in FIG. 20.

Referring to FIG. 25, an adhering support 60 may be provided. The thickness T3 of the auxiliary grid portions 63 and 65 may be thinner than the thickness T2 of the auxiliary edge portion 61, but in this embodiment, it is not necessarily limited thereto.

Next, referring to FIG. 26, the protective portion PF may be removed. The upper part of the adhering support 60 may then be brought into corresponding contact with the lower part of the support 30.

Subsequently, a laser L may be emitted from the upper part of the support 30. The laser L may be emitted in the downward direction (or, towards the adhering support 60) from the upper surface of the support 30 exposed through the slit lines SL. Weld beads WB1 and WB2 may be formed at the interface between the support 30 and the adhering support 60, and the adhering support 60 and the support 30 may be attached and connected by means of the weld beads WB1 and WB2. Since the slot lines SL are formed between the cell portions C and the neighboring cell portions C, providing empty spaces, even if the weld beads WB1 and WB2 protrude to a certain height, they do not exceed the height of the upper surface of the mask 20.

Then, subsequent processes such as cleaning may be performed to complete the producing of the mask-frame assembly 10 (10-6).

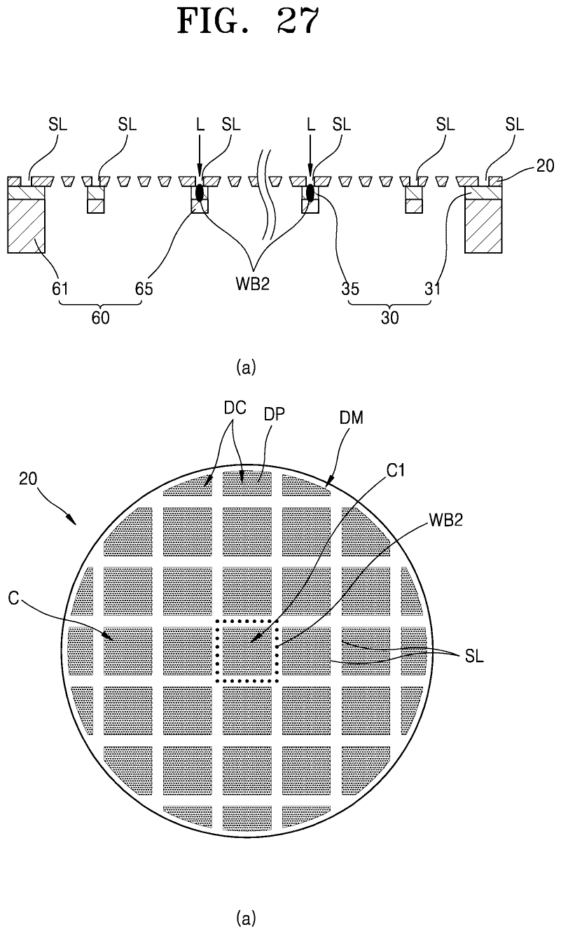

FIGS. 27 to 29 are schematic views specifically showing the process of connecting the support and the adhering support during the producing process of a mask-frame assembly according to the sixth embodiment of the present invention.

As described in FIG. 26, the laser L may be emitted to the surrounding areas of all cell portions C to attach and connect the support 30 and the adhering support 60. Alternatively, as shown in FIGS. 27 to 29, the support 30 and the adhering support 60 may be sequentially attached and connected on the surrounding area of each cell portion C.

First, referring to FIG. 27, a laser L may be emitted onto the surrounding area of the cell portion C1 located at the center of the mask 20 among the cell portions C. A weld bead WB2 may be formed at the interface between the support 30 (grid portions 33 and 35) and the adhering support 60 (auxiliary grid portions 63 and 65) on the surrounding area of the cell portion C1.

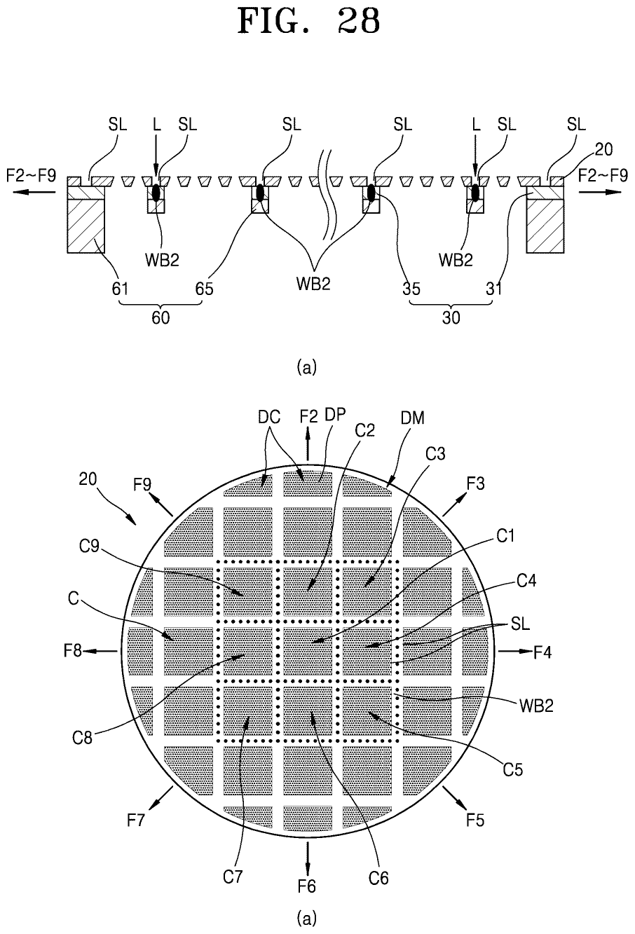

Next, referring to FIG. 28, a laser L may be emitted to the surrounding areas of eight cell portions C2 to C9 neighboring the cell portion C1. Weld beads WB2 may be formed at the interface between the support 30 (grid portions 33 and 35) and the adhering support 60 (auxiliary grid portions 63 and 65) on the surrounding areas of the cell portions C2 to C9.

Since the surrounding area or the cell portion C1 is fixed with the formed weld beads WB2, tensile forces F2 to F9 may be applied in a radial direction to the edges of the mask 20 and the support 30. By adjusting the tensile forces F2 to F9, the position alignment of each cell portion C2 to C9 may be further controlled. A laser L may be emitted simultaneously to the surrounding areas of the eight cell portions C2 to C9. Due to the relatively thin thickness T1 of the support 30, ranging from approximately 100 μm to 200 μm, the application of tensile forces F2 to F9 allows for position alignment of the cell portions C2 to C9.

Alternatively, tensile forces F2 to F9 may be applied sequentially from the cell portion C2 to the cell portion C9 in a radial direction or in a 360-degree direction and the laser L may be sequentially emitted to the surrounding areas of the cell portions C2 to C9, forming the weld beads WB2. For example, initially, in a state where tensile force F2 is applied in the upward direction to the mask 20 and the support 30, a laser L may be emitted onto the surrounding area of cell portion C2 to form the weld beads WB2 around cell portion C2. Subsequently, in a state where tensile force F3 is applied in the upper right direction to the mask 20 and the support 30, a laser L may be emitted onto the surrounding area of cell portion C3 to form the weld beads WB2 around cell portion C3. Subsequently, in a state where tensile force F4 is applied in the right direction to the mask 20 and the support 30, a laser L may be emitted onto the surrounding area of cell portion C4 to form the weld beads WB2 around cell portion C4. In a state where the surrounding areas of the cell portions C2 to C9 are sequentially aligned by repeating the above process, the support 30 and the adhering support 60 may be attached and connected.

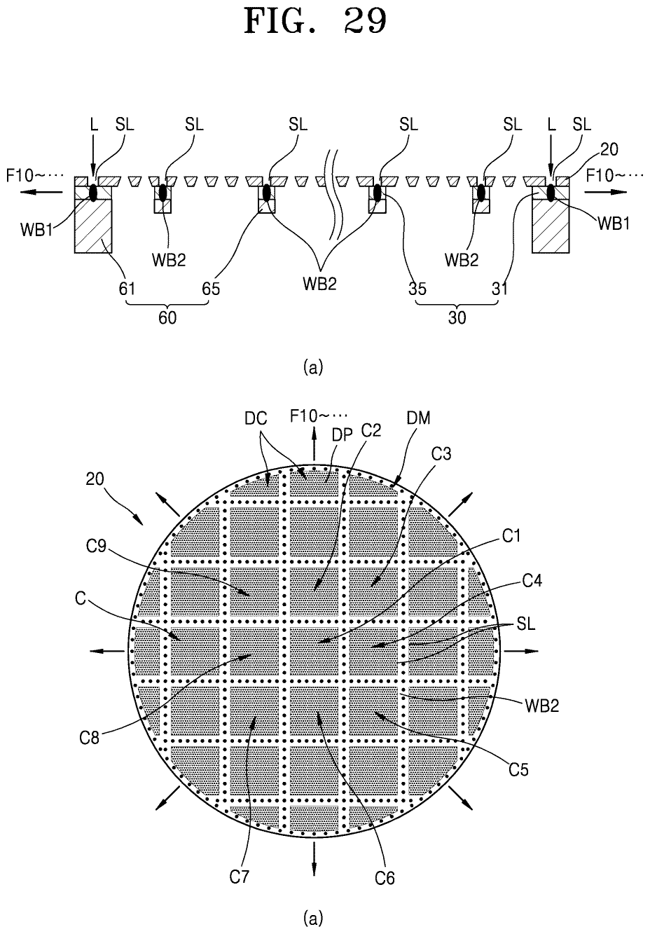

Next, referring to FIG. 29, a laser L may also be emitted onto the surrounding areas of cell portions C neighboring the eight cell portions C2 to C9 in FIG. 28. The surrounding areas of cell portions C neighboring the eight cell portions C2 to C9 may be simultaneously or sequentially welded and attached in a radial direction. In the dummy portion DM of the mask 20, weld beads WB1 may be formed at the interface between the support 30 (edge portion 31) and the adhering support 60 (auxiliary edge portion 61) through irradiation of laser L. During the process of adhering the cell portions C neighboring the eight cell portions C2 to C9, tensile forces F10, and so on may be applied to the edges of the mask 20 and the support 30 in a radial direction. This process may be repeated to connect the support 30 and the adhering support 60 on the surrounding areas of all cell portions C.

As described above, according to the present invention, the surroundings of the central cell portion C1 are first welded and connected, and the positions of outer cell portions C are aligned while the corresponding surroundings of each cell portion C are welded and connected. This allows for a clear determination of the positions of each cell portion C and the corresponding mask pattern P of the respective cell portion C. Accordingly, the variation in pixel position accuracy (PPA) between each cell portion C may be minimized.

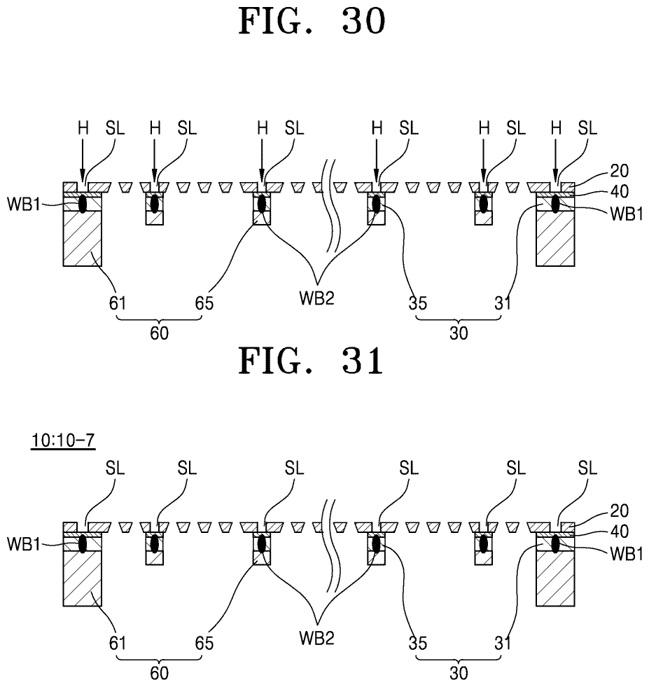

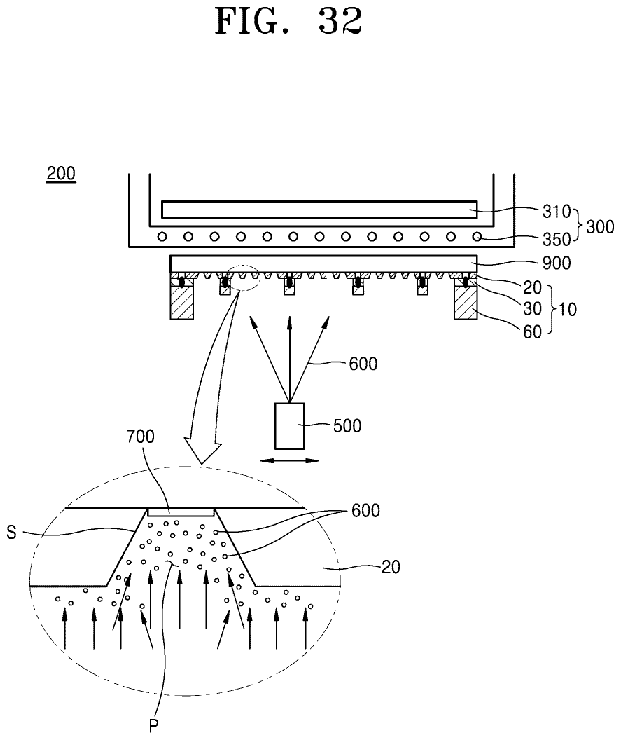

FIGS. 30 and 31 are schematic views showing the producing process of a mask-frame assembly 10 (10-7) according to a seventh embodiment of the present invention.

Referring to FIG. 30, after performing the processes described up to FIG. 26, heat treatment H may be further performed. Alternatively, heat treatment H may be performed on the support 30′, which is a conductive substrate 30′, after the mask 20 is electroformed (see FIG. 6). Heat treatment H may be performed on both the mask 20 and the support 30. The heat treatment may be performed in the temperature range of approximately 200° C. to 800° C.

As a result of the heat treatment H, the mask 20 and the support 30 may can be connected. During the heat treatment H process, a connection portion 40 may be formed between the mask 20 and the support 30. The heat treatment H may be applied in the same manner as described in FIG. 10 and FIG. 16.

Next, referring to FIG. 31, the mask-frame assembly 10 (10-7) according to the seventh embodiment may have the mask 20 connected onto the support 30 by interposing the connection portion 40 therebetween.

FIG. 32 is a schematic diagram of an OLED pixel deposition apparatus 200 to which a mask-frame assembly according to another embodiment of the present invention is applied.

Referring to FIG. 32, the OLED pixel deposition apparatus 200 includes a magnet plate 300 accommodating a magnet 310 and having cooling water lines 350 formed therein, and a deposition source supply 500 configured to supply an organic source 600 from below the magnet plate 300. The configuration of the OLED pixel deposition apparatus 200 is the same as described in FIG. 18. The above-described mask-frame assembly 10 (10-4 to 10-7) according to one of the fourth to seventh embodiments may be attached or placed very closely to the target substrate 900.

According to the present invention with the above-described configuration, it is possible to achieve ultra-high-resolution pixels for a microdisplay.

In addition, according to the present invention, it is possible to improve the stability of pixel deposition by clearly aligning a mask.

In addition, according to the present invention, it is possible to achieve a uniform stress level in all parts of a mask.

In addition, according to the present invention, the mask and frame can be brought into close contact with the target substrate without sagging due to load during the OLED pixel formation process.

However, the scope of the present invention is not limited by the above effects.

While the present invention has been particularly shown and described with reference to embodiments thereof, it will be understood by one of ordinary skill in the art that various changes in form and details may be made therein without departing from the scope of the present invention as defined by the following claims.

### REFERENCE NUMERALS

10: MASK-FRAME ASSEMBLY
20: MASK
30: SUPPORT
31: EDGE PORTION
33: FIRST GRID PORTION
35: SECOND GRID PORTION
40: CONNECTION PORTION
50: ADHESIVE PORTION
60: ADHERING SUPPORT
61: AUXILIARY EDGE PORTION
62: WELDING GROOVE
63: FIRST AUXILIARY GRID PORTION
65: SECOND AUXILIARY GRID PORTION
200: OLED PIXEL DEPOSITION APPARATUS
C, SR, DM: CELL PORTION, SEPARATION PORTION, DUMMY PORTION
DC: DUMMY CELL PORTION
DP: DUMMY PATTERN
P: MASK PATTERN
SL: SLIT LINE
WB1, WB2: WELD BEAD

What is claimed is:

1. A mask-frame assembly for use in a process of forming organic light-emitting diode (OLED) pixels on a semiconductor wafer, comprising:
a support comprising an edge portion and a grid portion;
a mask connected onto the support and including a mask pattern; and
an adhering support connected to a lower part of the support and comprising an auxiliary edge portion and an auxiliary grid portion,
wherein the adhering support includes a magnetic material.

2. The mask-frame assembly of claim 1, wherein a thickness of the adhering support is thicker than a thickness of the support.

3. The mask-frame assembly of claim 1, wherein the auxiliary grid portion has a thinner thickness than the auxiliary edge portion and a thickness of the auxiliary edge portion of the adhering support is thicker than a thickness of the support.

4. The mask-frame assembly of claim 1, wherein the adhering support and the support are connected to each other by means of a weld bead.

5. The mask-frame assembly of claim 4, wherein a welding groove is formed towards the support from an exposed surface of the auxiliary edge portion, and the weld bead is formed within the welding groove.

6. The mask-frame assembly of claim 4, wherein the weld bead is formed to protrude from an exposed surface of the auxiliary grid portion.

7. The mask-frame assembly of claim 1, wherein the edge portion of the support has a circular shape, the mask may have a circular shape, and the adhering support has a shape corresponding to the support.

8. The mask-frame assembly of claim 7, wherein the grid portion comprises:
a plurality of first grid portions extending in a first direction and having both ends connected to the edge portion; and
a plurality of second grid portions extending in a second direction perpendicular to the first direction, intersecting with the first grid portions, and having both ends connected to the edge portion.

9. The mask-frame assembly of claim 7, wherein the support is formed from a silicon wafer and the mask is formed on a conductive substrate by electroforming.

10. The mask-frame assembly of claim 8, wherein the mask comprises: a dummy portion connected onto the edge portion; a plurality of cell portions disposed at a central part of the mask and including a plurality of mask patterns; and separation portions positioned closer to the central part of the mask than the dummy portion and disposed between the plurality of cell portions and
the separation portions comprises a plurality of dummy cell portions including a plurality of dummy patterns formed to pass through the dummy portion or formed to a predetermined depth on the dummy portion.

11. The mask-frame assembly of claim 8, wherein each of the cell portions including the plurality of mask patterns has a rectangular shape and each dummy cell portion including the plurality of dummy patterns has a shape with at least some side exhibiting curvature.

12. The mask-frame assembly of claim 1, wherein an adhesive portion is interposed between the support and the adhering support and the adhesive portion comprises at least one of Cu, Au, Ag, Al, Sn, In, Bi, Zn, Sb, Ge, or Cd.

13. The mask-frame assembly of claim 9, wherein a connection portion is interposed between the support and the mask and the connection portion comprises at least one of Fe, Ni, or Si.

14. The mask-frame assembly of claim 9, wherein a surface resistance of the support is 5×10⁻⁴ ohm·cm to 1×10⁻² ohm·cm.

15. A producing method of a mask-frame assembly for use in a process of forming organic light-emitting diode (OLED) pixels on a semiconductor wafer, comprising the steps of:
(a) preparing a laminate of a support including an edge portion and a grid portion and a mask formed on the support by electroforming and including a mask pattern;
(b) preparing an adhering support including an auxiliary edge portion and an auxiliary grid portion; and
(c) connecting the adhering support onto a surface opposite to a surface of the support connected to the mask,
wherein the adhering support includes a magnetic material.

16. The producing method of claim 15, wherein step (a) comprises:
(a1) preparing a conductive substrate;
(a2) forming a mask including a mask pattern on a first surface of the conductive substrate; and
(a3) forming the support including the edge portion and the grid portion by etching the conductive substrate on a second surface opposite to the first surface of the conductive substrate.

17. The producing method of claim 16, wherein between steps (a2) and (a3), a protective portion is formed on the mask.

18. The producing method of claim 16, further comprising between steps (a2) and (a3),
(a2′) forming an adhesive portion including at least one of Cu, Au, Ag, Al, Sn, In, Bi, Zn, Sb, Ge, or Cd on a second surface opposite to a first surface of the conductive substrate,
wherein in step (3), the conductive substrate and the adhesive portion are etched.

19. The producing method of claim 18, wherein in step (c), heat treatment is performed on the support, the adhesive portion, and the adhering support to connect the support to the adhering support by means of the adhesive portion.

20. The producing method of claim 18, further comprising between steps (a2) and (a2′), or after step (c), forming a connection portion including at least one of Fe, Ni, or Si between the mask and the support by performing heat treatment on the mask and the support.
